(19) United States
(12) Patent Application Publication
(10) Pub. No.: US 2026/0026170 A1
(43) Pub. Date: Jan. 22, 2026

(54) DISPLAY PANEL, ELECTRONIC DEVICE INCLUDING THE SAME, AND DISPLAY PANEL MANUFACTURING METHOD

(71) Applicant: Samsung Display Co., Ltd., Yongin-si (KR)

(72) Inventors: DOKEUN SONG, Yongin-si (KR); JOONYONG PARK, Yongin-si (KR); SUKYOUNG YANG, Yongin-si (KR); SAMTAE JEONG, Yongin-si (KR)

(21) Appl. No.: 19/265,777

(22) Filed: Jul. 10, 2025

(30) Foreign Application Priority Data
Jul. 17, 2024 (KR) 10-2024-0094689
Mar. 7, 2025 (KR) 10-2025-0029427

(51) Int. Cl. H10H 29/49; G02B 27/01; H10H 29/01; H10K 59/12; H10K 59/131

(52) U.S. Cl. CPC H10H 29/49; H10H 29/012; H10K 59/1201; H10K 59/131; G02B 27/0172

(57) ABSTRACT

A display panel and a method of manufacturing the display panel are disclosed. The display panel may include a base layer, a circuit layer, and a display layer, wherein the circuit layer includes a lower conductive pattern, a lower insulation layer having a contact opening to expose a top surface of the lower conductive pattern, a bridge pattern directly on the lower conductive pattern in the contact opening and arranged to extend to a top surface of the lower insulation layer, a flat insulation layer including a fill insulation part filling the contact opening and a flat insulation layer spaced from the fill insulation part and not overlapping the bridge pattern to be on the lower insulation layer, an upper conductive pattern arranged flat on the fill insulation part and the bridge pattern and electrically connected to the first electrode, and an upper insulation layer on the upper conductive pattern.

### CROSS-REFERENCE TO RELATED APPLICATIONS

The present application claims priority to and the benefit of Korean Patent Application No. 10-2024-0094689, filed on Jul. 17, 2024, and Korean Patent Application No. 10-2025-0029427, filed on Mar. 7, 2025, in the Korean Intellectual Property Office, the entire contents of both of which are incorporated herein by reference.

### BACKGROUND

### 1. Field

One or more embodiments of the present disclosure relate to a display panel, an electronic device including the display panel, and a display panel manufacturing method (e.g., a method of manufacturing the display panel). For example, one or more embodiments of the present disclosure relate to a display panel with an improved (or enhanced) contact structure between vertically aligned conductive (e.g., electrically conductive) layers, an electronic device including the display panel, and a display panel manufacturing method (e.g., a method of manufacturing the display panel).

### 2. Description of the Related Art

Display devices are utilized for various suitable multimedia devices, such as televisions, mobile phones, tablet computers, and/or game machines, in order to provide image information to users. These display devices include a light-emitting element and a pixel circuit to drive the light-emitting element.

In arrangement of a pixel circuit, a driving circuit, and/or the like, it is desirable (e.g., required) to develop a technology to adjust the arrangement type (kind) of conductive (e.g., electrically conductive) layers constituting the circuits to increase (or enhance) integration (e.g., to increase a degree of integration) and maintain excellent (or suitable) electrical characteristics.

### SUMMARY

One or more aspects of embodiments of the present disclosure are directed toward a display panel and an electronic device including the display panel, wherein the display panel has the excellent or suitable electrical reliability and display quality by improving or enhancing the contact stability between a plurality of vertically aligned conductive (e.g., electrically conductive) patterns, vertically aligned conductive (e.g., electrically conductive) patterns and semiconductor patterns, or other vertically overlapping conductive (e.g., electrically conductive) layers.

One or more aspects of embodiments of the present disclosure are also directed toward a manufacturing method of a display panel (e.g., a method of manufacturing a display panel) including a connection electrode unit stably connecting a plurality of vertically aligned conductive (e.g., electrically conductive) patterns.

For example, one or more aspects of embodiments of the present disclosure are directed toward a display panel and an electronic device incorporating the display panel, which achieves excellent or suitable electrical reliability and display quality by enhancing the contact stability between one or more suitable vertically aligned conductive patterns and semiconductor patterns. Also, one or more aspects of embodiments of the disclosure are directed toward a method for manufacturing the display panel, featuring a connection electrode unit that ensures stable connections between the vertically aligned conductive patterns.

Additional aspects of embodiments will be set forth in part in the description which follows and, in part, will be apparent from the description or may be learned by practice of the presented embodiments of the disclosure.

In one or more embodiments of the present disclosure, a display panel includes: a base layer; a circuit layer on the base layer; and a display layer arranged on the circuit layer and including a light-emitting element including a first electrode, a second electrode being opposite to (e.g., facing) the first electrode, and a functional layer between the first electrode and the second electrode, wherein the circuit layer includes: a lower circuit layer including a plurality of conductive (e.g., electrically conductive) patterns and a plurality of interlayer insulation (e.g., electrical insulation) layers; a lower conductive (e.g., electrically conductive) pattern on the lower circuit layer; a lower insulation (e.g., electrical insulation) layer arranged on the lower conductive pattern and having a contact opening defined to expose a top surface of the lower conductive pattern; a bridge pattern arranged directly on the lower conductive pattern in the contact opening and arranged to extend to a top surface of the lower insulation layer; a flat (e.g., substantially flat) insulation (e.g., electrical insulation) layer including a fill insulation (e.g., electrical insulation) part filling the contact opening and a flat (e.g., substantially flat) insulation (e.g., electrical insulation) part spaced and/or apart (e.g., spaced apart or separated) from the fill insulation part and not overlapping the bridge pattern to be arranged on the lower insulation layer; an upper conductive (e.g., electrically conductive) pattern arranged flat on the fill insulation part and the bridge pattern and electrically connected to the first electrode; and an upper insulation (e.g., electrical insulation) layer on the upper conductive pattern.

In one or more embodiments, a top surface of the bridge pattern, a top surface of the fill insulation part, and a top surface of the flat insulation part may be coplanar.

In one or more embodiments, a bottom surface of the upper conductive pattern may be arranged to be spaced and/or apart (e.g., spaced apart or separated) from the lower insulation layer with the bridge pattern or the flat insulation layer arranged therebetween.

In one or more embodiments, an edge of the upper conductive pattern may overlap the bridge pattern.

In one or more embodiments, an edge of the upper conductive pattern may overlap the flat insulation part.

In one or more embodiments, side edges of the bridge pattern on the lower insulation layer may be covered with the flat insulation part.

In one or more embodiments, the fill insulation part may be surrounded by the bridge pattern and the upper conductive pattern.

In one or more embodiments, the first electrode may include: a contact electrode unit arranged in an opening defined in the upper insulation layer to directly contact the upper conductive pattern; and a flat (e.g., substantially flat) electrode unit provided integrally with the contact electrode unit to be arranged on the upper insulation layer.

In one or more embodiments, the lower circuit layer may include a first conductive (e.g., electrically conductive) pattern and a second conductive (e.g., electrically conductive) pattern spaced and/or apart (e.g., spaced apart or separated) from each other in a thickness direction, and the lower circuit layer may further include at least one connection electrode unit between the first conductive pattern and the second conductive pattern, wherein the at least one connection electrode unit may include: a bridge conductive (e.g., electrically conductive) unit including a bridge bending unit in an insulation (e.g., electrical insulation) opening defined through at least one of the plurality of interlayer insulation layers, and a bridge flat unit extending from the bridge bending unit to be arranged on an uppermost layer among the plurality of interlayer insulation layers in which the insulation opening is defined; and an interlayer insulation (e.g., electrical insulation) unit including a first insulation (e.g., electrical insulation) unit filling the insulation opening on the bridge bending unit and a second insulation (e.g., electrical insulation) unit having a top surface coplanar with a top surface of the bridge conductive unit and arranged on the uppermost layer.

In one or more embodiments, the at least one connection electrode unit may further include a flat (e.g., substantially flat) conductive (e.g., electrically conductive) unit arranged flat on the first insulation unit and the bridge flat unit and may be electrically connected with the bridge conductive unit.

In one or more embodiments, the circuit layer may include: a first connection electrode unit connected to the first conductive pattern and including a first bridge conductive (e.g., electrically conductive) unit and a first interlayer insulation (e.g., electrical insulation) unit; and a second connection electrode unit arranged on the first connection electrode unit and including a second bridge conductive (e.g., electrically conductive) unit and a second flat insulation (e.g., electrical insulation) part, wherein each of the first bridge conductive unit and the second bridge conductive unit includes the bridge bending unit and the bridge flat unit, and the bridge flat unit of the first bridge conductive unit is directly connected with the bridge bending unit of the second bridge conductive unit.

In one or more embodiments, the display layer may include a first light-emitting element including a first functional layer, a second light-emitting element including a second functional layer, and a third light-emitting element including a third functional layer, wherein the first light-emitting element, the second light-emitting element, and the third light-emitting element are to emit light beams in different wavelength regions, and the circuit layer may include a first upper conductive (e.g., electrically conductive) pattern electrically connected with the first light-emitting element, a second upper conductive (e.g., electrically conductive) pattern electrically connected with the second light-emitting element, and a third upper conductive (e.g., electrically conductive) pattern electrically connected with the third light-emitting element, wherein a distance between the first functional layer and the first upper conductive pattern, a distance between the second functional layer and the second upper conductive pattern, and a distance between the third functional layer and the third upper conductive pattern are different from each other.

In one or more embodiments of the present disclosure, an electronic device includes: a display module including a display panel and configured or arranged to provide an image; and a power module configured or arranged to supply power to the display module, wherein the display panel includes: a base layer; a circuit layer on the base layer; and a display layer arranged on the circuit layer and including a light-emitting element including a first electrode, a second electrode being opposite to (e.g., facing) the first electrode, and a functional layer between the first electrode and the second electrode, wherein the circuit layer includes: a lower circuit layer including a plurality of conductive (e.g., electrically conductive) patterns and a plurality of interlayer insulation (e.g., electrical insulation) layers; a lower conductive (e.g., electrically conductive) pattern on the lower circuit layer; a lower insulation (e.g., electrical insulation) layer arranged on the lower conductive pattern and having a contact opening defined to expose a top surface of the lower conductive pattern; a bridge pattern arranged directly on the lower conductive pattern in the contact opening and arranged to extend to a top surface of the lower insulation layer; a flat (e.g., substantially flat) insulation (e.g., electrical insulation) layer including a fill insulation (e.g., electrical insulation) part filling the contact opening and a flat (e.g., substantially flat) insulation (e.g., electrical insulation) part spaced and/or apart (e.g., spaced apart or separated) from the fill insulation part and not overlapping the bridge pattern to be arranged on the lower insulation layer; an upper conductive (e.g., electrically conductive) pattern arranged flat on the fill insulation part and the bridge pattern and electrically connected to the first electrode; and an upper insulation (e.g., electrical insulation) layer on the upper conductive pattern.

In one or more embodiments, the display module may further include a light control panel on the display panel, wherein the light control panel may include a color filter layer and a lens pattern on the color filter layer.

In one or more embodiments, the electronic device may further include at least one of a processor or a memory, wherein the electronic device may be an image display device, a wearable device, and/or a vehicle device.

In one or more embodiments, the bridge pattern may include a bridge bending unit in the contact opening, and a bridge flat unit extending from the bridge bending unit to be arranged on the lower insulation layer, and a top surface of the bridge flat unit, a top surface of the fill insulation part, and a top surface of the flat insulation part may be coplanar.

In one or more embodiments, side edges of the bridge pattern on the lower insulation layer may be covered with the flat insulation part, and the fill insulation part may be surrounded by the bridge pattern and the upper conductive pattern.

For example, one or more embodiments of the present disclosure describe a display panel with improved or enhanced electrical reliability and display quality, achieved by enhancing the contact stability between two or more conductive layers. It may include a base layer, a circuit layer, and a display layer with light-emitting elements that emit different wavelengths of light. The circuit layer may have two or more conductive patterns and insulation layers, with a bridge pattern ensuring stable connections. The display panel may be part of an electronic device, which may include a light control panel and components like a processor or a memory, suitable for one or more suitable applications, such as image display devices, wearable devices, and/or vehicle devices.

In one or more embodiments of the present disclosure, a display panel manufacturing method (e.g., a method of manufacturing a display panel) includes: providing a lower conductive (e.g., electrically conductive) pattern over a lower circuit layer arranged on a base layer; providing a lower insulation (e.g., electrical insulation) layer in which a contact opening defined to expose at least a portion of a top surface of the lower conductive pattern; providing a bridge pattern including a bending unit in the contact opening and a flat (e.g., substantially flat) unit extending from the bending unit to be arranged on the lower insulation layer; providing a preliminary flat insulation (e.g., electrical insulation) layer covering the bridge pattern and arranged on the lower insulation layer; providing a flat (e.g., substantially flat) insulation (e.g., electrical insulation) layer by removing a portion of the preliminary flat insulation layer so as to include a top surface that is coplanar with a top surface of the bridge pattern; providing an upper conductive (e.g., electrically conductive) pattern on the bridge pattern; providing an upper insulation (e.g., electrical insulation) layer in which an opening is defined to expose at least a portion of a top surface of the upper conductive pattern; and providing, on the upper insulation layer, a display layer including a light-emitting element electrically connected with the upper conductive pattern.

In one or more embodiments, the providing of the flat insulation layer may include flattening a top surface of the preliminary flat insulation layer with at least one of chemical mechanical polishing or etching. For example, the provision of the flat insulation layer may include flattening the top surface of the preliminary flat insulation layer with (utilizing) at least one of chemical mechanical polishing or etching.

In one or more embodiments, the providing of the flat insulation layer may be providing the flat insulation layer on the bending unit so that (or such that) the flat insulation layer includes a fill insulation (e.g., electrical insulation) part being on the bending unit to be arranged in the contact opening and a flat (e.g., substantially flat) insulation (e.g., electrical insulation) part spaced and/or apart (e.g., spaced apart or separated) from the fill insulation part and not overlapping the bridge pattern. For example, the provision of the flat insulation layer may include providing the flat insulation layer on the bending unit such that the flat insulation layer includes a fill insulation part arranged in the contact opening on the bending unit and a flat insulation part spaced from the fill insulation part, not overlapping the bridge pattern.

For example, one or more embodiments of the present disclosure describe a method for manufacturing a display panel that involves one or more steps (e.g., acts or tasks), such as: adding a lower conductive pattern on a base layer, covering it with a lower insulation layer that has an opening, and placing a bridge pattern in the opening. Then, a preliminary flat insulation layer is added and partially removed to create a flat surface. An upper conductive pattern is placed on the bridge pattern, followed by an upper insulation layer with an opening. Finally, a display layer with a light-emitting element connected to the upper conductive pattern is added. The flat insulation layer may be made utilizing polishing or etching and includes parts that fill the opening and parts that do not overlap the bridge pattern.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a block diagram of an electronic device according to one or more embodiments;

FIG. 2 is schematic diagrams of an electronic device according to one or more embodiments;

FIG. 3A is a perspective view of an electronic device according to one or more embodiments;

FIG. 3B is a perspective view of an electronic device according to one or more embodiments;

FIG. 4 is a plan view of a display device according to one or more embodiments;

FIG. 5 is an equivalent circuit of any one pixel among pixels as illustrated in FIG. 4;

FIG. 6 is a cross-sectional view of a display module according to one or more embodiments;

FIG. 7 is a plan view of a partial area of the display module according to one or more embodiments;

FIG. 8 is a cross-sectional view of the partial area of the display module according to one or more embodiments;

FIG. 9 is a cross-sectional view of a display panel according to one or more embodiments;

FIG. 10 is an enlarged view of area XX of FIG. 9;

FIG. 11 is a cross-sectional view of a display panel according to one or more embodiments;

FIG. 12 is a cross-sectional view of a display panel according to one or more embodiments;

FIG. 13 is a cross-sectional view of a display panel according to one or more embodiments;

FIG. 14 is a cross-sectional view of a display panel according to one or more embodiments;

FIG. 15 is a flowchart illustrating a display panel manufacturing method (e.g., a method of manufacturing a display panel) according to one or more embodiments; and

FIGS. 16A-16G each illustrates one step (e.g., act or task) of the display panel manufacturing method according to one or more embodiments.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items. For example, “A and/or B” indicates cases where it is A, or B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

It will be understood that if (e.g., when) an element or a layer is referred to as being “on,” “connected to,” or “coupled to” another element or layer, it may be directly on, directly connected to, or directly coupled to the other element or layer, or intervening third elements or layers may be present therebetween. In contrast, if (e.g., when) an element or a layer is referred to as being “directly on,” “directly connected to,” or “directly coupled to” another element or layer, there are no intervening elements or layers present therebetween.

In the drawings, the thickness, the ratio, and the dimension of the element may be exaggerated for effective description of the technical contents.

The terms, such as “first,” “second,” and/or the like, may be used to describe one or more suitable elements, but these elements should not be limited by the terms. These terms are only used to distinguish one element, component, region, layer, or portion from another element, component, region, layer, or portion. For example, without departing from the scope of the present disclosure, a first element, a first component, a first region, a first layer, or a first portion may be referred to as a second element, a second component, a second region, a second layer, or a second portion, and similarly, the second element, the second component, the second region, the second layer, or the second portion may be referred to as the first element, the first component, the first region, the first layer, or the first portion.

The singular expressions include plural expressions unless the context clearly dictates otherwise.

The terms, such as “below,” “lower,” “above,” “upper,” and/or the like, are used to describe the relationship of the configurations or arrangements as illustrated in the drawings. The terms are used as a relative concept and are described with reference to the direction indicated in the drawings.

It should be understood that the terms “include,” “including, “have,” and/or “having” are intended to specify the presence of stated features, integers, steps, operations, elements, components, and/or one or more (e.g., any suitable) combinations thereof in the present disclosure, but do not preclude the presence or addition of one or more other features, integers, steps, operations, elements, components, and/or one or more (e.g., any suitable) combinations thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms used herein have substantially the same meaning as generally understood by one of ordinary skill in the art to which example embodiments belong.

It will be understood that terms, such as those defined in generally-used or generally-available dictionaries, should be interpreted as having a meaning that is substantially consistent with their meaning in the context of the relevant art and will not be interpreted in an idealized or overly formal sense unless expressly so defined herein.

In the following embodiments, the x-axis, y-axis, and z-axis are not limited to three axes in an orthogonal coordinate system, but may be interpreted in a broader sense including them. For example, the x-axis, y-axis, and z-axis may be orthogonal to each other or may refer to different directions that are not orthogonal to each other.

Hereinafter, a display panel according to one or more embodiments, an electronic device according to one or more embodiments, and a display panel manufacturing method (e.g., a method of manufacturing a display panel) according to one or more embodiments will be described in more detail with reference to the drawings.

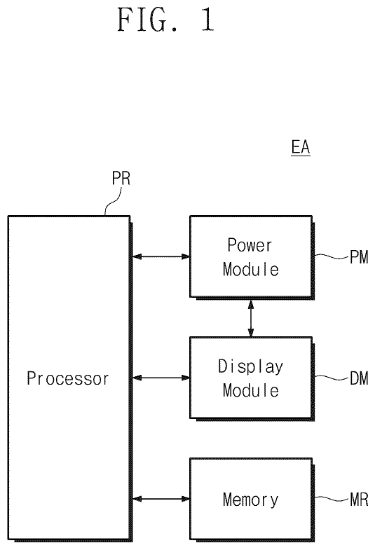

FIG. 1 is a block diagram of an electronic device according to one or more embodiments. Referring to FIG. 1, the electronic device EA according to one or more embodiments may include a display module DM, a processor PR, a memory MR, and a power module PM.

The processor PR may include at least one of a central processing unit (CPU), an application processor, a graphic processing unit (GPU), a communication processor (CP), an image signal processor (ISP), or a controller.

The memory MR may be to store data information desired or required for the operation of the processor PR and/or the display module DM. If (e.g., when) the processor PR executes an application stored in the memory MR, an image data signal and/or an input control signal may be transferred to the display module DM, and the display module DM may be to process the received signal to output image information via a display screen. The display module DM may include a display panel configured or arranged to display an image.

The power module PM may include a power supply module, such as a power adapter, a battery device, and/or the like, and a power conversion module configured or arranged to convert the power supplied from the power supply module to generate power desired or required for the operation of the electronic device EA.

At least one selected from among the elements of the electronic device EA according to one or more embodiments may be included in a display device including a display module according to one or more embodiments. In one or more embodiments, one or more of individual modules functionally included in one module may be included in the display device, and the other may be provided separately from the display device. For example, the display device may include the display module DM, and the processor PR, the memory MR, and the power module PM may be provided in another device other than the display device in the electronic device EA.

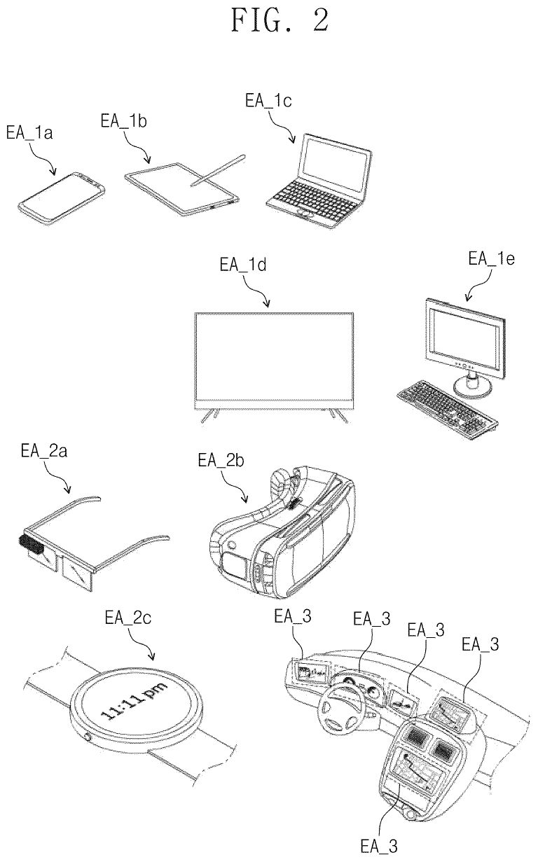

FIG. 2 is schematic diagrams of an electronic device according to one or more embodiments.

Referring to FIG. 2, one or more suitable electronic devices including the display device according to one or more embodiments may include not only an electronic device for an image display, such as a smartphone EA_1a, a tablet PC (EA_1B), a laptop (EA_1c), a TV (EA_1a), a desk monitor (EA_1e), and/or the like, but also a wearable electronic device, such as smart glasses (EA_2a), a head-mounted display (EA_2b), a smartwatch (EA_2c), and/or the like, and/or a vehicle electronic device EA_3, such as a vehicle dashboard, a center fascia, a center information display (CID) arranged on the dashboard, a room mirror display, and/or the like.

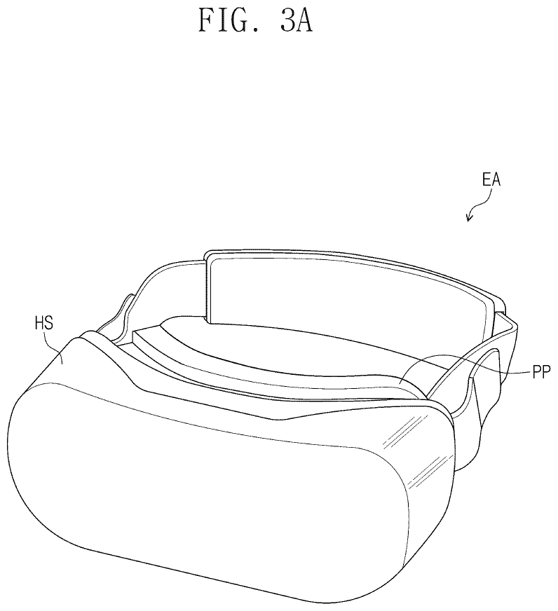

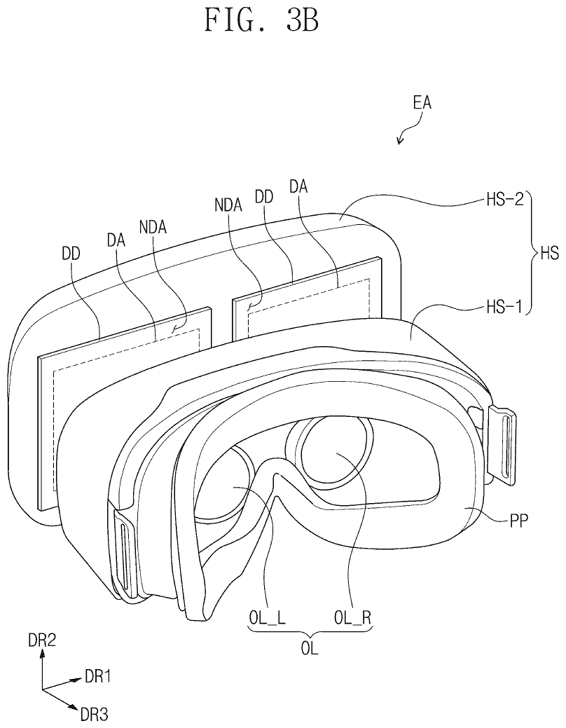

FIGS. 3A and 3B are respective perspective views illustrating an electronic device according to one or more embodiments. FIGS. 3A and 3B illustrate a head-mounted display as an example electronic device EA.

The electronic device EA according to one or more embodiments as described with reference to FIGS. 3A and 3B may provide an image in a state in which the actual around (e.g., surrounding) field of view of a user is blocked. The user wearing the electronic device EA may be easily immersed in virtual reality.

The electronic device EA may include a plurality of display devices DD. The electronic device EA may include a display device DD, a body unit HS, a cushion unit PP, and/or the like. In one or more embodiments, the electronic device EA may further include one or more suitable sensors, a camera, and/or the like.

The body unit HS may be mounted on the head of the user. Inside the body unit HS, the display device DD configured or arranged to display an image, an acceleration sensor, and/or the like may be accommodated. The acceleration sensor may be to sense the movement of the user and transfer a prescribed signal to the display device DD. Accordingly, the display device DD may be to provide an image corresponding to a gaze change of the user. Accordingly, the user may experience virtual reality like the actual reality. The display device DD may include a display module DM (see FIG. 6) according to one or more embodiments. In one or more embodiments, elements of the display device DD included in the electronic device EA according to one or more embodiments may be provided to include elements other than the elements of the display module DD to be described with reference to FIG. 6 and/or the like in correspondence to the characteristics of a wearable device.

Components having one or more suitable functions other than those disclosed in one or more embodiments may be accommodated in the body unit HS. For example, an operation unit and/or the like configured or arranged to adjust the volume or screen brightness may be additionally arranged outside the body unit HS. The operation unit may be provided with a physical button or in the type (kind) of a touch sensor and/or the like. In one or more embodiments, the body unit HS may be to accommodate a proximity sensor configured or arranged to determine whether the user wears the device. In one or more embodiments, the body unit HS may further include an external display panel.

The body unit HS may be divided into a main body HS-1 and a cover HS-2. FIG. 3 illustrates an example type (kind) in which the main body HS-1 is separated from the cover HS-2, but embodiments of the present disclosure are not limited thereto. For example, the main body HS-1 and the cover HS-2 may be integrally provided and not be separated from each other.

The display devices DD may be provided between the main body HS-1 and the cover HS-2. Each of the display devices DD may provide an image via a display area DA. Each of the display devices DD may include a non-display area NDA around (e.g., surrounding) the display area DA. In one or more embodiments, the non-display area NDA in one or more embodiments may be arranged only at one side of the display area DA or may not be provided.

FIG. 3B illustrates an example in which a left eye image and a right image are provided via separated display devices DD, but embodiments of the present disclosure are not limited thereto. For example, the left eye image and the right eye image may be displayed via one display device. For example, the electronic device EA may include one display device.

In one or more embodiments, the display devices DD may be driven by separate driving units, or the plurality of display devices DD may be driven by one driving unit. The display devices DD may be to generate an image corresponding to input image data.

The cushion unit PP may be arranged between the body unit HS and the user head. The cushion unit PP may be composed of a material of which the shape is substantially freely modified. For example, the cushion unit PP may be composed of a polymer resin (e.g., polyurethane, polycarbonate, polypropylene, polyethylene, and/or the like), or a sponge foamed with a rubber liquid, a urethane-based resin, an acrylic-based resin, and/or the like. However, embodiments of the present disclosure are not limited thereto.

The cushion unit PP may be to cause the body unit to be close to the user to improve or enhance a user wearing sensation experience. The cushion unit PP may be detachable from the body unit HS. The cushion unit PP in one or more embodiments of the present disclosure may not be provided.

An optical system OL may be arranged inside the main body HS-1 of the body unit HS. The optical system OL may be to enlarge the images provided from the display devices DD. Via the display area DA parallel (e.g., substantially parallel) to a first direction DR1 and a second direction DR2 crossing (e.g., intersecting) with the first direction DR1, each of the display devices DD may be to display the image in a third direction DR3. The optical system OL may be arranged to be spaced and/or apart (e.g., spaced apart or separated) from the display device DD in the third direction DR3. The optical system OL may be arranged between the display devices DD and the user eyes. The optical system OL may include a right eye optical system OL_R and a left eye optical system OL_L. The left eye optical system OL_L may be to enlarge the image to provide the enlarged image to the user left pupil, and the right eye optical system OL_R may be to enlarge the image to provide the enlarged image to the user right pupil.

The left eye optical system OL_L may be arranged to be spaced and/or apart (e.g., spaced apart or separated) from the right eye optical system OL_R in the first direction DR1. The distance between the left eye optical system OL_L and the right eye optical system OL_R may be adjusted corresponding to the distance between the two eyes of the user. Furthermore, the distance between the optical system OL and the display devices DD may be adjusted according to the eyesight of the user.

The optical system OL may be a convex aspherical lens. For example, the optical system OL may include a pancake lens, but embodiments of the present disclosure are not limited thereto. In one or more embodiments, a case may be described in which each of the left eye optical system OL_L and the right eye optical system OL_R is composed of one lens, but embodiments of the present disclosure are not limited thereto. For example, each of the left eye optical system OL_L and the right eye optical system OL_R may include a plurality of lenses.

The display device DD, included in the electronic device EA according to one or more embodiments as described with reference to FIGS. 3A and 3B, may include an organic light-emitting display panel, an inorganic light-emitting display panel, an organic-inorganic light-emitting display panel, a quantum dot display panel, a micro-LED display panel, or a nano-LED display panel. In the present disclosure, a case may be described in which the display devices DD each includes an organic light-emitting display panel as a display panel, but embodiments of the present disclosure are not limited thereto. The display device DD included in the electronic device EA according to one or more embodiments may have the high resolution characteristics.

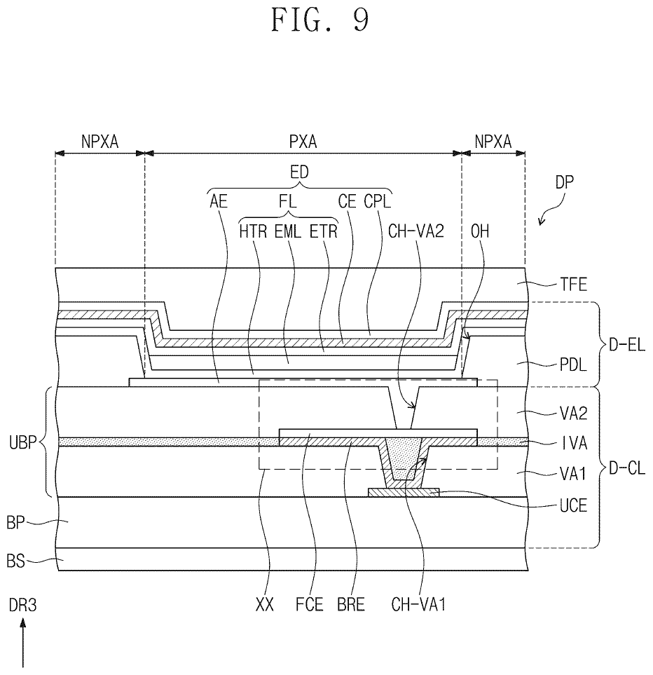

The display device DD according to one or more embodiments may have the ultra-high resolution display quality, and thus a first electrode (or a pixel electrode) in a light-emitting element ED (FIG. 9) included in the display device DD and multiple conductive (e.g., electrically conductive) patterns configured or arranged to operate and control the light-emitting element ED (FIG. 9) may be provided with fine patterns with high precision. In one or more embodiments, the conductive (e.g., electrically conductive) patterns may be aligned in a vertical direction (a thickness direction) so that (or such that) the multiple conductive patterns are arranged in a limited area.

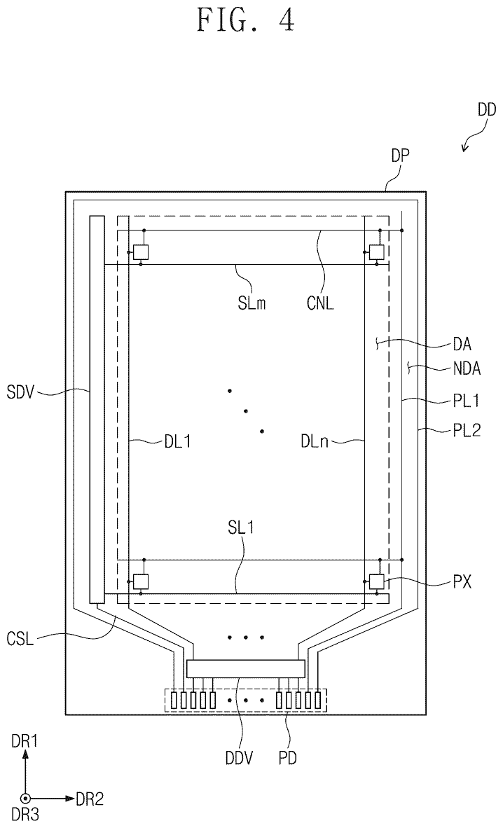

FIG. 4 is a plan view of a display device according to one or more embodiments. In one or more embodiments, the display device DD may include a display panel DP, a scan driver SDV, a data driver DDV, and a plurality of pads PD.

If (e.g., when) viewed from the third direction DR3, the display panel DP may have a rectangular shape (e.g., a substantially rectangular shape) having long sides extending in the first direction DR1 and short sides extending in the second direction DR2, but the shape of the display panel DP is not limited thereto. The display panel DP may include the display area DA and the non-display area NDA around (e.g., surrounding) the display area DA.

In one or more embodiments, the third direction DR3 may be defined as a direction substantially normal (e.g., perpendicular) to a plane defined by the first direction DR1 and the second direction DR2. The front surface (or top surface) and the rear surface (or bottom surface) of each member that constitute the electronic device EA may be opposite to each other in the third direction DR3, and each normal direction of the front surface and the rear surface may be substantially parallel to the third direction DR3. The separation distance between the front surface and the rear surface defined along the third direction DR3 may correspond to the thickness of the member.

In the present disclosure, the expression “in plan view” may refer to a state of being viewed in the third direction DR3. For example, “in plan view” may be described on the basis of a plane defined by the first direction DR1 and the second direction DR2. In one or more embodiments, the expression “in a cross-sectional view” may refer to a state viewed in the first direction DR1 or the second direction DR2. In one or more embodiments, directions indicated by the first to third directions DR1, DR2, and DR3 are relative concepts and may be changed to other directions.

The display panel DP may include a plurality of pixels PX, a plurality of scan lines SL1 to SLm, a plurality of data lines DL1 to DLn, a control line CSL, first and second power lines PL1 and PL2, and connection lines CNL. Herein, m and n are natural numbers.

The pixels PX may be arranged in the display area DA. The pixels PX may be arranged in a matrix type (kind), but the arrangement type (kind) of the pixels PX is not limited thereto.

The scan driver SDV may be arranged in the non-display area NDA adjacent to one of the long sides of the display panels DP. If (e.g., when) viewed in plan view, the scan driver SDV may be adjacent to the left side of the display panel DP.

The data driver DDV may be arranged in the non-display area NDA adjacent to any one of the short sides of the display panel DP. If (e.g., when) viewed in plan view, the data driver DDV may be adjacent to the bottom end of the display panel DP.

The scan lines SL1 to SLm may extend in the second direction DR2 to be connected to the pixels PX and the scan driver SDV. The data lines DL1 to DLn may extend in the first direction DR1 to be connected to the pixels PX and the data driver DDV.

The first power line PL1 may extend in the first direction DR1 to be arranged in the non-display area NDA. The first control line PL1 may be adjacent to one long side, at which the scan driver SDV is not arranged, of the display panel DP.

The connection lines CNL may extend in the second direction DR2 and be arranged in the first direction DR1 to be connected to the first power line PL1 and the pixels PX. A first voltage may be applied to the pixels PX via the first power line PL1 and the connection lines CNL that are connected to each other.

The second power line PL2 may be arranged in the non-display area NDA and extend along the long sides of the display panel DP and the other short side, at which the data driver DDV is not arranged, of the display device DP. The second power line PL2 may be arranged in the outer side than the scan driver SDV.

In one or more embodiments, the second power line PL2 may extend towards the display area DA to be connected to the pixels PX. A second voltage may be applied to the pixels PX via the second power line PL2.

The control line CSL may be connected to the scan driver SDV and extend towards the bottom end of the display panel DP. A control signal to control the operation of the scan driver SDV may be provided to the scan driver SDV via the control line CSL.

The pads PD may be arranged in the non-display area NDA adjacent to the bottom end of the display panel DP and may be more adjacent to the bottom end of the display panel DP than the data driver DDV is. The data driver DDV, the first and second power lines PL1 and PL2, the control line CSL may be connected to the pads PD. The data lines DL1 to DLn may be connected to the data driver DDV, and the data driver DDV may be connected to the pads PD corresponding to the data lines DL1 to DLn.

In one or more embodiments, the display device DD may further include a timing controller configured or arranged to control the operations of the scan driver SDV and the data driver DDV and a voltage generation unit configured or arranged to generate the first and second voltages. The timing controller and the voltage generation unit may be mounted on a printed circuit board and connected to the pads PD via the printed circuit board.

The scan driver SDV may be to generate a plurality of scan signals, and the scan signals may be applied to the pixels PX via the scan lines SL1 to SLm. The data driver DDV may be to generate a plurality of data voltages, and the data voltages may be applied to the pixels PX via the data lines DL1 to DLn.

The pixels PX may be provided with data voltages in response to the scan signals. The pixels PX may be to display an image by emitting light of the brightness corresponding to the data voltages.

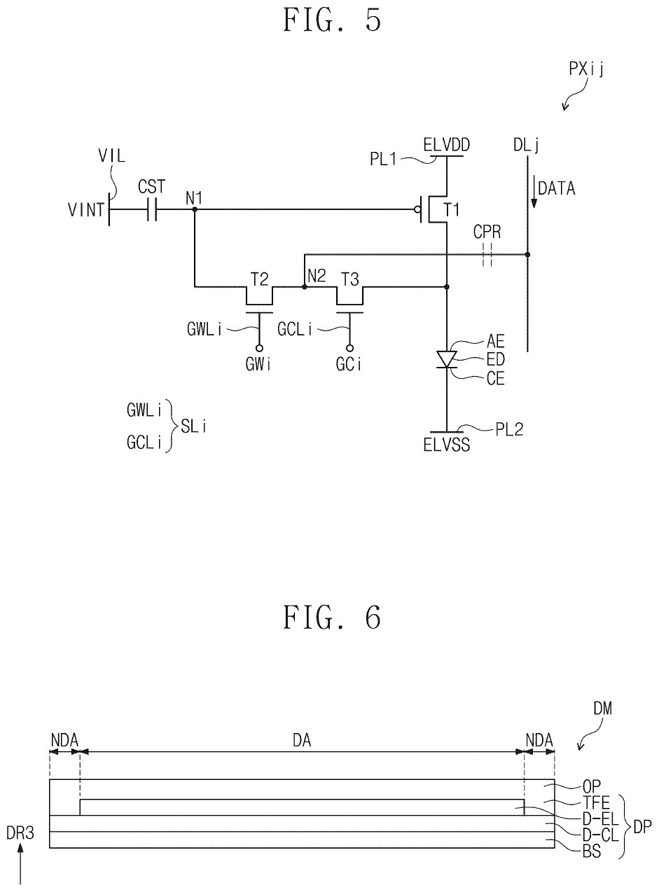

FIG. 5 illustrates an equivalent circuit of any one of the pixels as illustrated in FIG. 4.

By way of an example, FIG. 5 illustrates a pixel PXij connected to an i-th scan line SLi and a j-th data line DLj. Herein, i and j are natural numbers. For convenience of description, “i-th” and “j-th” may not be provided.

Referring to FIG. 5, the pixel PXij may include a first transistor T1, a second transistor T2, a third transistor T3, a light-emitting element ED, and a capacitor CST.

The scan line SLi may include a write scan line GWLi and a compensation scan line GCLi. The write scan line GWLi may be to receive the write scan signal GWi, and the compensation scan line GCLi may be to receive the compensation scan signal GCi.

In one or more embodiments, a parasite capacitor CPR may be provided between the data line DLj and a second node N2 between the second transistor T2 and the third transistor T3. However, the parasite capacitor CPR may not be an element of the pixel PXij, and thus the description of the parasite capacitor CPR may not be provided in the description of the operation of the pixel PXij.

The light-emitting element ED may be defined as an organic light-emitting element. The light-emitting element ED may include a first electrode AE and a second electrode CE. The first electrode AE may be connected to the first power line PL1 via the first transistor T1. The second electrode CE may be connected to the second power line PL2. The first power line PL1 may be to receive a first voltage ELVDD. The second power line PL2 may be to receive a second voltage ELVSS having the lower level than the first voltage ELVDD.

The first transistor T1 may be a positive-type (kind) metal-oxide-semiconductor transistor (or a PMOS transistor). The second and third transistors T2 and T3 may be negative-type (kind) metal-oxide-semiconductor transistors (or NMOS transistors). The first transistor T1 may include a silicon semiconductor, and the second and third transistors T2 and T3 may include an oxide semiconductor.

Each of the first, second, and third transistors T1, T2 and T3 may include a source electrode, a drain electrode, and a gate electrode. Hereinafter, for convenience, one selected from the source electrode and the drain electrode in FIG. 5 may be defined as a first electrode unit and the other may be defined as a second electrode unit. In one or more embodiments, the gate electrode may be defined as a control electrode unit.

The first transistor T1 may be defined as a driving transistor, and the second transistor T2 may be defined as a switching transistor. The third transistor T3 may be defined as a compensation transistor.

The first transistor T1 may be connected to the first power line PL1 and the first electrode AE of the light-emitting element ED and may be switched according to a voltage of a first node N1. The first transistor T1 may include the first electrode unit connected to the first power line PL1, the second electrode unit connected to the electrode AE of the light-emitting element ED, and a control electrode unit connected to the first node N1. The first transistor T1 may be turned on by the voltage of the first node N1. The first node N1 may be defined as the control electrode unit of the first transistor T1.

The second transistor T2 may be connected to the first node N1 and the second node N2. For example, the second transistor T2 may be connected a gate electrode unit of the first transistor T1 and the data line DLj. The second transistor T2 may be switched by the write scan signal GWi.

The second transistor T2 may include a first electrode unit connected to the first node N1, a second electrode unit connected to the second node N2, and a control electrode unit connected to the write scan line GWLi. The second transistor T2 may be turned on by the write scan signal GWi applied via the write scan line GWLi.

The third transistor T3 may be connected to the second node N2 and the first electrode AE of the light-emitting element ED and may be switched by the compensation scan signal GCi. The third transistor T3 may include a first electrode unit connected to the second node N2, a second electrode unit connected to the first electrode AE of the light-emitting element ED, and a control electrode unit connected to the compensation scan line GCLi. The third transistor T3 may be turned on by the compensation scan signal GCi applied via the compensation scan line GWLi.

The data line DLj may be connected to the second node N2. Accordingly, the data line DLj may be connected to the second electrode unit of the second transistor T2 and the first electrode unit of the third transistor T3. The data line DLj may be to receive a data signal DATA.

The first electrode AE of the light-emitting element ED may be connected to the first power line PL1 via the first transistor T1, and a cathode CE of the light-emitting element ED may be connected to the second power line PL2.

The capacitor CST may include a first electrode unit connected to an initialization line VIL and a second electrode unit connected to the first node N1. The initialization line VIL may be to receive an initialization voltage VINT.

The write scan signal GWi applied to the control electrode unit of the second transistor T2 may be a global clock signal for concurrent (e.g., simultaneous) emission driving. For example, if (e.g., when) the display device DD operates in a concurrent (e.g., simultaneous) emission driving method, the write scan signal GWi, which is the global clock signal, may be applied to the pixels PX in common.

FIG. 6 is a cross-sectional view of a display module according to one or more embodiments. The display device DD according to one or more embodiments as described with reference to FIGS. 3A to 4 may include a display module DM configured or arranged provide an image. The display module DM may include a display area DA and a non-display area NDA. The display area DA and the non-display area NDA of the display module DM may correspond to the display area DA and the non-display area NDA of the display device DD of the display device DD according to one or more embodiments as described with reference to FIGS. 3A to 4.

The display module DM according to one or more embodiments may include a display panel DP. Referring to FIG. 6, the display panel DP included in the display module DM according to one or more embodiments may include a base layer BS, a circuit layer D-CL arranged on the base layer BS, a display layer D-EL arranged on the circuit layer D-CL, and an encapsulation layer TFE arranged on the display layer D-EL.

The base layer BS may be a member configured or arranged to provide a base surface on which the circuit layer D-CL and the display layer D-EL are arranged. The base layer BS may include a plastic substrate, a glass substrate, a metal substrate, an organic/inorganic composite material substrate, and/or the like. In one or more embodiments, the base layer BS may be a silicon substrate, a germanium substrate, and/or a silicon on insulator (SOI) substrate. However, embodiments of the present disclosure are not limited thereto, and the base layer BS may be an inorganic layer, an organic layer, or a composite material layer.

In one or more embodiments, the circuit layer D-CL may be arranged on the base layer BS and include a plurality of conductive (e.g., electrically conductive) patterns and a plurality of interlayer insulation (e.g., electrical insulation) layers. The plurality of conductive patterns may constitute a circuit element including signal lines, a pixel driving circuit, and/or the like. In one or more embodiments, the circuit layer D-CL may include a plurality of transistors constituted of the plurality of conductive patterns. For example, the circuit layer D-CL may include a switching transistor and a driving transistor configured or arranged to drive the light-emitting elements ED of the display layer D-EL.

The display layer D-EL may include a plurality of light-emitting elements. The light-emitting elements ED (FIG. 9) each may include a light-emitting layer configured or arranged to emit light.

The encapsulation layer TFE may be arranged on the circuit layer D-CL so as to cover the display layer D-EL. The encapsulation layer TFE may be to protect the pixels from moisture, oxygen, and/or foreign matters. The encapsulation layer TFE may include a plurality of thin films. One or more of the thin films may be arranged to enhance the optical efficiency, and the other may be arranged to protect the light-emitting elements.

The display module DM according to one or more embodiments may further include a light control panel OP arranged on the display panel DP. The light control panel OP may be arranged on the encapsulation layer TFE. The light control panel OP may be to transmit or block (or reduce) a portion of the light provided from the display layer D-EL. In one or more embodiments, the light control panel OP may include an optical layer and/or the like to collect light from the display layer D-EL or control a light output direction. The light control panel OP will be described in more detail herein.

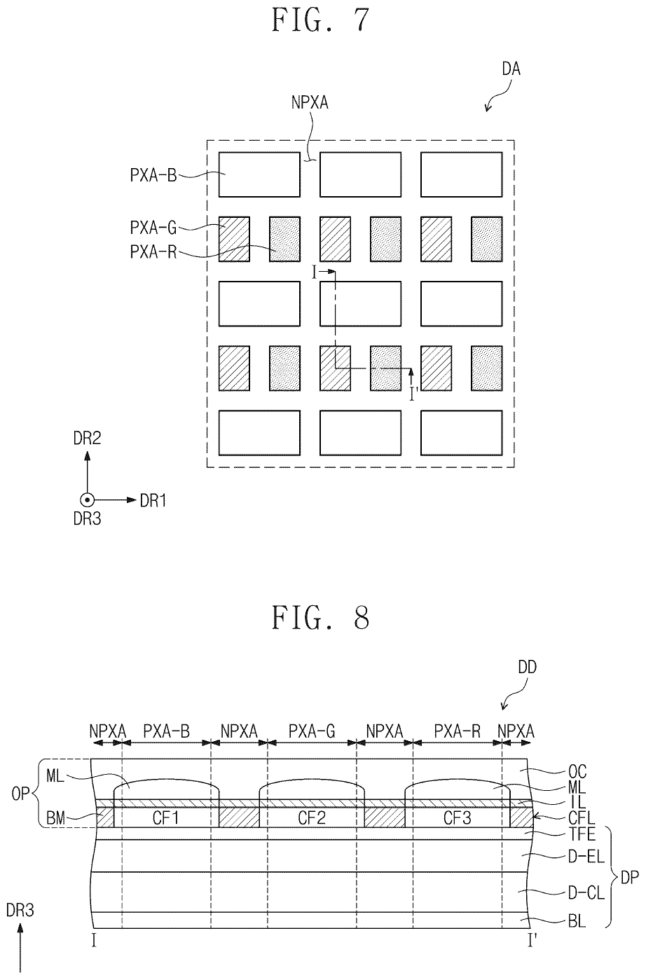

FIG. 7 is an enlarged plan view of a portion of the display module according to one or more embodiments. FIG. 7 illustrates a portion of the display area DA of the display module DM (FIG. 6). FIG. 7 illustrates the arrangement of emission areas PXA-B, PXA-G, and PXA-R in the display module DM (FIG. 6) according to one or more embodiments.

The display module according to one or more embodiments may include a plurality of emission areas PXA-B, PXA-G, and PXA-R spaced and/or apart (e.g., spaced apart or separated) from each other in plan view, and a peripheral area NPXA between the emission areas PXA-B, PXA-G, and PXA-R.

The display module according one or more embodiments may include three types (kinds) of emission areas PXA-B, PXA-G, and PXA-R that are distinguished from each other. In one or more embodiments, the three types (kinds) of emission areas PXA-R, PXA-G, and PXA-B as illustrated in FIG. 7 may be repeatedly arranged in the entire display area DA. The emission areas PXA-R, PXA-G, and PXA-B may be referred to as pixel areas.

The display area DA may include a first emission area PXA-B, a second emission area PXA-G, and a third emission area PXA-R that are to emit light beams at different frequency regions and are spaced and/or apart (e.g., spaced apart or separated) from each other in plan view. In one or more embodiments, the display area DA may include the peripheral area NPXA. The peripheral area NPXA may be referred to as a non-emission area.

The peripheral area NPXA may be arranged around the first to third emission areas PXA-B, PXA-G, and PXA-R. The peripheral area NPXA may set the boundaries of the first to third emission areas PXA-R, PXA-G, and PXA-B. The peripheral area NPXA may be around (e.g., surround) the first to third emission areas PXA-R, PXA-G, and PXA-B. Structures configured or arranged to prevent or reduce color mixing between the first to third emission areas PXA-R, PXA-G, and PXA-B, for example, a pixel definition layer PDL (FIG. 9) and/or the like may be arranged corresponding thereto in the peripheral area NPXA.

The first to third emission areas PXA-R, PXA-G, and PXA-B may respectively correspond to areas from which light beams provided from the first to third emission areas PXA-R, PXA-G, and PXA-B are emitted. The first to third emission areas PXA-R, PXA-G, and PXA-B may be divided according to colors of light beams emitted towards the outside.

The first to third emission areas PXA-R, PXA-G, and PXA-B may provide first to third color light beams with different colors. For example, the first color light beam may be red light, the second color light beam may be green light, and the third color light beam may be blue light. However, the example of the first to third light beams is not limited thereto.

Each of the first to third emission areas PXA-B, PXA-G, and PXA-R may correspond to an area in which the top surface of the first electrode AE (FIG. 9) of the light-emitting element is exposed by a pixel opening OH (FIG. 9) to be described in more detail herein.

Each of the first to third emission areas PXA-B, PXA-G, and PXA-R may be provided in plurality to be repetitively arranged and have a prescribed arrangement type (kind) in the display area DA. For example, the first emission areas PXA-B may be arranged along the first direction DR1 to compose “a first group.” The second and third emission areas PXA-G and PXA-R may be alternately arranged along the first direction DR1 to compose “a second group.” Each of the “first group” and “second group” may be provided in plurality, and the “first group” and “second group” may be alternately arranged along the second direction DR2.

FIG. 7 illustrates an example arrangement type (kind) of the first to third emission areas PXA-B, PXA-G, and PXA-R, and embodiments of the present disclosure are not limited thereto. The emission areas may be arranged in one or more suitable types (kinds). In one or more embodiments, the first to third emission areas PXA-R, PXA-G, and PXA-B may have a PENTILE® arrangement type (kind) (e.g., an RGBG matrix, RGBG structure, or RGBG matrix structure), but embodiments of the present disclosure are not limited thereto. In one or more embodiments, the first to third emission areas PXA-R, PXA-G, and PXA-B may have a stripe arrangement type (kind) or a DIAMOND PIXEL™ arrangement type (kind). PENTILE® is a duly registered trademark of Samsung Display Co., Ltd., and DIAMOND PIXEL™ is a trademark of Samsung Display Co., Ltd.

The first to third emission areas PXA-R, PXA-G, and PXA-B may have one or more suitable shapes in plan view. For example, the first to third emission areas PXA-R, PXA-G, and PXA-B may have the shape of a polygon (e.g., a substantially polygon), a circle (e.g., a substantially circle), an ellipse (e.g., a substantially ellipse), and/or the like. FIG. 7 illustrates an example in which the first to third emission areas PXA-R, PXA-G, and PXA-B have a rectangular shape (e.g., a substantially rectangular shape) in plan view.

The first to third emission areas PXA-R, PXA-G, and PXA-B may have substantially the same shape or at least partially different shapes in plan view. FIG. 7 illustrates a case in which the first to third emission areas PXA-R, PXA-G, and PXA-B have substantially the same shape in plan view.

At least a portion of the first to third emission areas PXA-R, PXA-G, and PXA-B may have different areas in plan view. In one or more embodiments, the area of the first emission area PXA-B from which the blue light is emitted may be larger than the area of each of the second emission area PXA-G from which the green light is emitted and the third emission area PXA-R form which the red light is emitted. However, the size relationship of the area between the first to third emission areas PXA-R, PXA-G, and PXA-B according to the emission color is not limited thereto and may vary according to a design of the display device according to one or more embodiments. In one or more embodiments, embodiments of the present disclosure are not limited thereto, and the first to third emission areas PXA-R, PXA-G, and PXA-B may have substantially the same area in plan view.

In one or more embodiments, the shapes, the areas, the arrangement, and/or the like of the first to third emission areas PXA-B, PXA-G, and PXA-R in the display device according to one or more embodiments may be suitably designed according to the size, the configuration or arrangement, and/or the like of the display device included in an electronic device and are not limited to one or more embodiments as illustrated in FIG. 7. For example, other than the first to third emission areas PXA-B, PXA-G, and PXA-R, the display module in one or more embodiments may further include an emission area from which white light is emitted.

FIG. 8 is a cross-sectional view of a display module according to one or more embodiments. FIG. 8 is a cross-sectional view taken along the line I-I′ of FIG. 7. As described with reference to FIG. 6 and/or the like, the display device DD according to one or more embodiments may include a display panel DP and a light control panel OP arranged on the display panel DP. In one or more embodiments, the display panel DP may include a base layer BS, a circuit layer D-CL, a light-emitting element layer D-EL, and an encapsulation layer TFE.

In one or more embodiments, the light control panel OP may include a color filter layer CFL and a lens pattern ML. The light control panel OP may further include at least one of an upper cover layer OC or an intermediate cover layer IL except the color filter layer CFL and the lens pattern ML.

The color filter layer CFL may include a partition pattern BM and at least one selected from among color filters CF1, CF2, and CF3. The color filters CF1, CF2, and CF3 may be to transmit light of a specific (e.g., set or predetermined) wavelength range and block or reduce light in outside the wavelength range. In one or more embodiments, the first color filter CF1 may be a blue filter, the second color filter may be a blue green filter, and the third color filter CF3 may be a red color filter.

Each of the color filters CF1, CF2, and CF3 may include a polymer photosensitive resin and/or a colorant. The colorant may include a pigment and/or a dye. The first color filter CF1 may include a blue pigment and/or a blue dye, the second color filter CF2 may include a green pigment and/or a green dye, and the third color filter CF3 may include a red pigment and/or a red dye. In one or more embodiments, the first color filter CF1 may not include a pigment and/or a dye.

The first to third color filters CF1, CF2, and CF3 may be respectively arranged corresponding to the first pixel area PXA-R, the second pixel area PXA-G, and the third pixel area PXA-B.

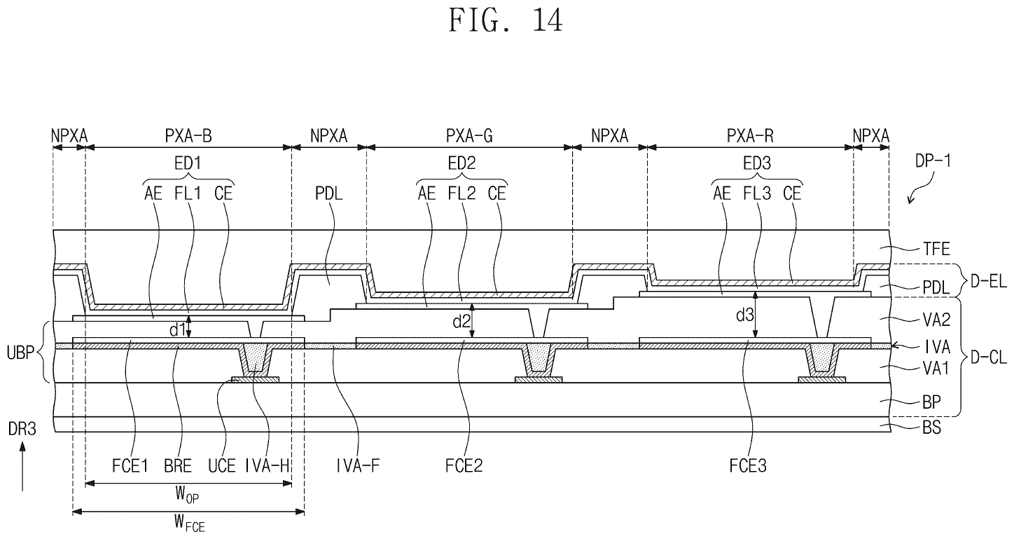

The color filters CF1, CF2, and CF3 may be arranged corresponding to openings defined in the partition pattern BM. The color filters CF1, CF2, and CF3 may be to transmit light beams provided from light-emitting elements ED1, ED2, and ED3 (FIG. 14) overlapping in correspondence to the respective color filters CF1, CF2, and CF3. The color reproduction of the light beams provided from the light-emitting elements ED1, ED2, and ED3 (FIG. 14) may be improved or enhanced by the color filters CF1, CF2, and CF3. In one or more embodiments, a light beam in a specific (e.g., set or predetermined) wavelength range among the light beams provided from the light-emitting elements ED1, ED2, and ED3 (FIG. 14) may be transmitted by the color filters CF1, CF2, and CF3.

In one or more embodiments, the color filter layer CFL in one or more embodiments may not include (e.g., may exclude) the partition pattern (e.g., may exclude any partition pattern) but may include a plurality of overlapping color filters CF1, CF2, and CF3 configured or arranged to transmit different light beams in correspondence to the peripheral area NPXA. In one or more embodiments, in correspondence to the peripheral area NPXA, the plurality of overlapping color filters CF1, CF2, and CF3 may be arranged in the third direction DR3, which is the thickness direction, and thus the boundaries between the adjacent emission areas PXA-B, PXA-G, and PXA-R may be distinguished. In one or more embodiments, the color filter layer CFL may not include (e.g., may exclude) the partition pattern (e.g., may exclude any partition pattern), and the intermediate cover layer IL may be arranged to fill between the color filters CF1, CF2, and CF3.

A material composing the partition pattern BM may not be limited as long as the material absorbs light. The partition pattern BM may have a black color and include a black coloring agent in one or more embodiments. The black coloring agent may include a black dye and/or a black pigment. The black coloring agent may include carbon black, a metal, such as chromium, and/or an oxide thereof.

The lens pattern ML may be arranged to overlap each of the emission areas PXA-B, PXA-G, and PXA-R. The lens pattern ML may be arranged on the color filter layer CFL. The lens pattern ML may be arranged over each of the color filters CF1, CF2, and CF3. The lens pattern ML may have the shape protruding in a direction spaced and/or apart (e.g., spaced apart or separated) from the display panel DP. The lens pattern ML may have a lens shape (e.g., a substantially lens shape). The lens pattern ML may be referred to as a microlens. However, the shape of the lens pattern ML is not limited thereto. The lens pattern ML may be provided with a material having a different refractive index from the upper cover layer OC. The lens pattern ML may be to control the output direction of light emitted from the light-emitting element ED (FIG. 9) or improve or enhance light extraction efficiency. However, embodiments of the present disclosure are not limited thereto.

The intermediate cover layer IL may be arranged on the color filter layer CFL. The intermediate cover layer IL may cover the color filters CF1, CF2, and CF3, and the partition pattern BM. In one or more embodiments, if (e.g., when) the partition pattern BM is not provided, the intermediate cover layer IL may be arranged to fill the top surface of the color filters CF1, CF2, and CF3 and the spaces between the color filters. The intermediate cover layer IL may be provided with an organic material including a polymer resin. For example, the intermediate cover layer IL may be provided with an organic resin including an acrylic-based resin, an epoxy-based resin, and/or the like. However, embodiments of the present disclosure are not limited thereto. In one or more embodiments, the intermediate cover layer IL in one or more embodiments may not be provided.

The upper cover layer OC may be arranged on the color filter layer CFL and the lens pattern ML. The upper cover layer OC may cover the color filter layer CFL and the lens pattern ML. The upper cover layer OC may be provided with an organic material including a polymer resin. For example, the upper cover layer OC may be provided with an organic resin including an acrylic-based resin, an epoxy-based resin, and/or the like. However, embodiments of the present disclosure are not limited thereto.

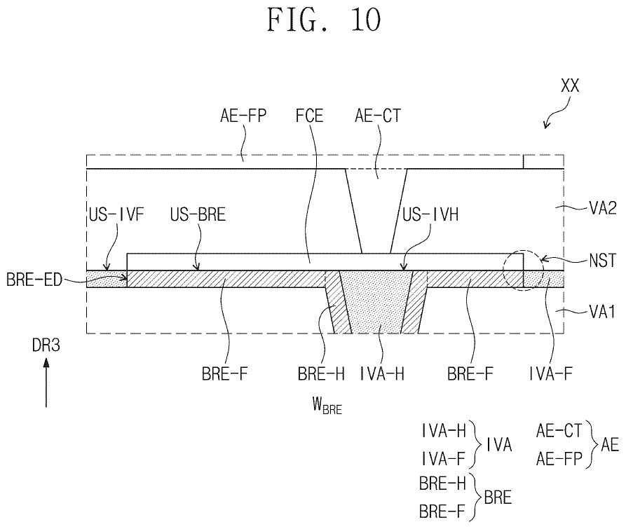

FIG. 9 is a cross-sectional view of a portion of a display panel according to one or more embodiments. FIG. 10 is an enlarged cross-sectional view of area XX of FIG. 9. FIG. 9 illustrates a portion of the display panel DP including one emission area PXA and the peripheral area NPXA adjacent to the emission area PXA. The emission area PXA as illustrated in FIG. 9 is a representative one of the first to third emission areas as illustrated in FIG. 8. The display panel DP of FIG. 9 includes the emission area PXA and the peripheral area NPXA, and the description of the display panel to be described in more detail herein may also be applied to the first to third emission areas PXA-B, PXA-G, and PXA-R.

The display panel DP according to one or more embodiments may include a base layer BS, a circuit layer D-CL, a light-emitting element layer D-EL, and an encapsulation layer TFE. The circuit layer D-CL may include a lower circuit layer BP and an upper circuit layer UBP.

The display layer D-EL may include a light-emitting element ED. The light-emitting element ED may include a first electrode AE, a second electrode CE being opposite to the first electrode AE, and a functional layer FL arranged between the first electrode AE and the second electrode CE. The functional layer FL may include a light-emitting layer EML. In one or more embodiments, the functional layer FL may further include a hole transport region HTR arranged between the first electrode AE and the light-emitting layer EML and an electron transport region arranged between the light-emitting layer EML and the second electrode. In one or more embodiments, the light-emitting element ED may further include a capping layer CPL arranged on the second electrode CE. In one or more embodiments, the display layer D-EL may include a pixel definition layer PDL separating the different light-emitting elements EM from each other.

The first electrode AE may be exposed through a pixel opening OH in the pixel definition layer PDL. The first electrode AE may have the conductivity (e.g., electrical conductivity). The first electrode AE may be composed of a metal material, a metal alloy, and/or a conductive (e.g., electrically conductive) compound. The first electrode AE may be an anode or a cathode. In one or more embodiments, the first electrode AE may be a pixel electrode. The first electrode AE may be a transparent electrode, a semi-transparent electrode, or a reflective electrode.

The second electrode CE may be arranged on the first electrode AE. The second electrode CE may be arranged to be opposite to (e.g., to face) the first electrode AE with the light-emitting layer between the first electrode AE and the second electrode CE. The second electrode CE may be an anode or a cathode. In one or more embodiments, if (e.g., when) the first electrode AE is an anode, the second electrode CE may be a cathode, and if (e.g., when) the first electrode AE is a cathode, the second electrode CE may be an anode. The second electrode CE may be a common electrode. The second electrode CE may be a transparent electrode, a semi-transparent electrode, or a reflective electrode.

The first electrode AE may be patterned to be arranged so as to correspond to the emission area PXA. The second electrode CE may be provided as a common layer to all the emission area PXA and the non-emission area NPXA.

The hole transport region HTR may be arranged between the first electrode AE and the light-emitting layer EML, and the electron transport region ETR may be arranged between the light-emitting layer EML and the second electrode CE. In one or more embodiments, each of the hole transport region HTR and the electron transport region ETR may be provided as a common layer to all the emission areas PXA-R, PXA-G, and PXA-B (FIG. 8). However, embodiments of the present disclosure are not limited thereto, and each of the hole transport region HTR and the electron transport region ETR may be separately provided to each of the emission areas PXA-R, PXA-G, and PXA-B (FIG. 8).

In one or more embodiments, the light-emitting layer EML may be arranged inside the pixel opening OH. For example, the light-emitting layer EML in one or more embodiments may be separately arranged to correspond to each of the emission areas PXA-R, PXA-G, and PXA-B (FIG. 8). The light-emitting layer EML may include an organic material and/or an inorganic material. The light-emitting layer EML may be to generate light of one selected from among red color, green color, and blue color.

In one or more embodiments, the light-emitting element ED may further include a capping layer CPL arranged over the second electrode CE. The capping layer CPL may include multiple layers or a single layer. The capping layer CPL in the display panel DP according to one or more embodiments may be provided as a common layer to all the emission areas PXA-R, PXA-G, and PXA-B (FIG. 8).

In one or more embodiments, the first electrode AE of the light-emitting element ED may include a contact electrode unit AE-CT and a flat electrode unit AE-FP. The contact electrode unit AE-CT and the flat electrode unit AE-FP may be integrally provided. The contact electrode unit AE-CT may be arranged in an opening CH-VA2 defined in an upper insulation layer VA2 arranged under the display layer D-EL. The contact electrode unit AE-CT arranged in the opening CH-VA2 of the upper insulation layer VA2 may directly contact an upper conductive pattern FCE in the lower side.

The lower circuit layer BP may include a plurality of conductive (e.g., electrically conductive) patterns and a plurality of interlayer insulation (e.g., electrical insulation) layers. The plurality of conductive patterns of the lower circuit layer BP may compose a transistor, a power line, signal lines, a capacitor, an electrode unit, and/or the like.

The upper circuit layer UBP may be arranged on the lower circuit layer BP and may include a connection electrode unit electrically connected to the transistor, the power line, the signal lines, the capacitor, the electrode unit, and/or the like of the lower circuit layer. In one or more embodiments, the connection electrode unit of the upper circuit layer UBP may electrically connect the lower circuit layer BP and the light-emitting element ED of the display layer D-EL.

The circuit layer D-CL may include a lower conductive pattern UCE, a lower insulation layer VA1, a bridge pattern BRE, a flat insulation layer IVA, an upper conductive pattern FCE, and an upper insulation layer VA2 arranged over the lower circuit layer BP. The circuit layer D-CL may also include a portion of the first electrode AE of the light-emitting element ED. In one or more embodiments, the configuration or arrangement in which the lower conductive pattern UCE, the bridge pattern BRE, and the upper conductive pattern FCE, which are electrically connected, and the flat insulation layer IVA arranged therebetween may be referred to as the connection electrode unit. The connection electrode unit may correspond to a configuration or arrangement to improve or enhance the contact stability between the conductive pattern under the connection electrode unit and the conductive pattern arranged over the connection electrode.

The lower conductive pattern UCE may be arranged on the lower circuit layer BP. The lower insulation layer VA1 may be arranged on the lower conductive pattern UCE. A contact opening CH-VA1 exposing a portion of the top surface of the lower conductive pattern UCE may be defined in the lower insulation layer VA1. The lower conductive pattern VA1 may be arranged to cover the lower circuit layer BP. In one or more embodiments, the top surface of the lower insulation layer VA1 may provide a flat surface (e.g., a substantially flat surface) to the elements arranged on the lower insulation layer VA1 except for an area in which the contact opening CH-VA1 is defined.

The bridge pattern BRE may be arranged on the lower circuit layer BP. The bridge pattern BRE may be connected to the lower conductive pattern UCE in the contact opening CH-VA1. Referring FIGS. 9 and 10, the bridge pattern BRE may be arranged directly on the lower conductive pattern UCE in the contact opening CH-VA1 and extend to the top surface of the lower insulation layer VA1. The bridge pattern BRE may include a bending unit BRE-H and a flat unit BRE-F. The bending unit BRE-H of the bridge pattern BRE may be arranged along the shape of the contact opening CH-VA1 of the lower insulation layer VA1 and be arranged directly on the lower conductive pattern UCE in the lower side.

The flat insulation layer IVA included in the circuit layer D-CL may include a fill insulation part IVA-H and the flat insulation part IVA-F. The fill insulation part IVA-H may be a portion to fill the contact opening CH-VA1. The flat insulation part IVA-F may be a portion arranged on the lower insulation layer VA1. The flat insulation part IVA-F may be arranged to be spaced and/or apart (e.g., spaced apart or separated) from the fill insulation part IVA-H and not overlap the bridge pattern BRE.

In one or more embodiments, a bridge pattern top surface US-BRE, a fill insulation part top surface US-IVH, and a flat insulation part top surface US-IVF may be coplanar. The flat insulation layer IVA may be provided to form a flat surface (e.g., a substantially flat surface) with the top surface US-BRE of the bridge pattern BRE arranged on the lower insulation layer VA1.

In one or more embodiments, the flat insulation part IVA-F may not be arranged to overlap the conductive pattern, such as the bridge pattern BRE, and may overlap the exposed entire top surface of the lower insulation layer VA1. However, embodiments of the present disclosure are not limited thereto. In one or more embodiments, the flat insulation part IVA-F may be arranged to cover an exposed side surface BRE-ED of the bridge pattern BRE and overlap the lower insulation layer VA1 within a range in which a conductive (e.g., electrically conductive) pattern arranged on the bridge pattern BRE is provided without a step at an upper portion of the bridge pattern and an outer portion adjacent to the bridge pattern BRE.

The fill insulation part IVA-H may be arranged inside the contact opening CH-VA1 to be surrounded by the bridge pattern BRE and the upper conductive pattern FCE. FIG. 9 illustrates only one cross-sectional state parallel (e.g., substantially parallel) to the third directional axis DR3, but a side surface and the top surface of the fill insulation part IVA-H of the display panel DP according to one or more embodiments may respectively contact the bridge pattern BRE and the upper conductive pattern FCE to be covered by the conductive patterns in entirety.

The circuit layer D-CL may include the upper circuit layer FCE arranged on the bridge pattern BRE. The upper conductive pattern FCE may be arranged to be flat (e.g., substantially flat) on the fill insulation part IVA-H and the bridge pattern BRE. In one or more embodiments, as described with reference to FIGS. 9 and 10, the upper conductive pattern FCE may be arranged on the flat surface defined by the fill insulation part top surface US-IVH and the bridge pattern top surface US-BRE. For example, in one or more embodiments, the edges of the upper conductive pattern FCE may overlap the bridge pattern BRE. However, embodiments of the present disclosure are not limited thereto. If (e.g., when) the width of the upper conductive pattern FCE is larger than the width of the bridge pattern BRE in one direction, the upper conductive pattern FCE may be arranged on the flat surface defined by the fill insulation part top surface US-IVH, the bridge pattern top surface US-BRE, and the flat insulation part top surface US-IVF. In one or more embodiments, the edges of the upper conductive pattern FCE may overlap the flat insulation part IVA-F.

In one or more embodiments, the upper conductive pattern FCE may be electrically connected with the first electrode AE of the display layer D-EL. The upper conductive pattern FCE may electrically connect the first electrode AE and the bridge pattern BRE. In one or more embodiments, via the laminate structure of the upper conductive pattern FCE, the bridge pattern BRE, and the lower conductive pattern UCE, the light-emitting element ED may be electrically connected with the conductive patterns of the lower circuit layer BP.

In one or more embodiments, the upper conductive pattern FCE may not be arranged directly on the lower insulation layer VA1. The bottom surface of the upper conductive pattern FCE may be arranged to be spaced and/or apart (e.g., spaced apart or separated) from the lower insulation layer VA1 with the bridge pattern BRE or the flat insulation layer IVA arranged therebetween.

The upper conductive pattern FCE may be arranged on the flat surface defined by the bridge pattern BRE and the flat insulation layer IVA, and thus the upper conductive pattern FCE may have the shape of a stepless flat layer except edge portions NST. For example, due to the bridge pattern BRE and the flat insulation layer IVA, the upper conductive pattern FCE may be provided as the flat surface without an influence of a bend and/or a step of the lower circuit layer BP or the lower insulation layer VA1. Accordingly, in the display panel DP according to one or more embodiments, a light scattering issue, which may occur due to external light reflection if (e.g., when) the upper conductive pattern FCE has a step, may be reduced (or a degree or occurrence of such light scattering issue may be reduced). Accordingly, the display quality of the display panel DP according to one or more embodiments and a display device including the display panel DP may be improved or enhanced.

The circuit layer D-CL may include an upper insulation layer VA2 arranged on the upper conductive pattern FCE. An opening CH-VA2 exposing a portion of the top surface of the upper conductive pattern FCE may be defined in the upper insulation layer VA2. The upper insulation layer VA2 may expose a portion of the top surface of the upper insulation layer VA2 in the opening CH-VA2 and be arranged on the upper conductive pattern FCE and the flat insulation layer IVA.

A portion of the first electrode AE may be arranged in the opening CH-VA2 in the upper insulation layer VA2. The contact-electrode unit AE-CT of the first electrode AE may be arranged in the opening CH-VA2 to directly contact the upper conductive pattern FCE.

The lower insulation layer VA1 and the upper insulation layer VA2 included in the upper circuit layer UBP of the display panel DP according to one or more embodiments may include organic layers. In one or more embodiments, the flat insulation layer IVA may include an inorganic layer. However, the material composition of the insulation (e.g., electrical insulation) layer is not limited thereto.

The upper conductive pattern FCE in the display panel DP according to one or more embodiments may be stably connected in a sufficient or suitable area to the flat unit BRE-F of the bridge pattern BRE provided to have the flat (e.g., substantially flat) top surface on the lower insulation layer VA1. Due to a stable contact between the upper conductive pattern FCE and the bridge pattern BRE, the electrical stability may be improved or enhanced in the display panel DP according to one or more embodiments. As the upper conductive pattern FCE stably comes in flat contact with the bridge pattern BRE in a large area, it may also be feasible to stably maintain electrical connections between the conductive patterns of the light-emitting element ED and the lower circuit layer BP configured or arranged to drive and control the light-emitting element ED.

In one or more embodiments, as the upper conductive pattern FCE, which composes the connection electrode unit in the display panel DP according to one or more embodiments, is stably arranged in a large area on the flat surface defined by the bridge pattern BRE and the flat insulation layer IVA, the degree of freedom of the disposition or arrangement of the electrodes or conductive (e.g., electrically conductive) patterns electrically connected with the upper conductive pattern FCE may increase. For example, in one or more embodiments, the position of the contact electrode unit AE-CT, which is a portion of the first electrode AE, may be substantially freely adjusted within a range in which the flat electrode unit AE-FP of the first electrode AE and the upper conductive pattern FCE may be electrically connected.

In one or more embodiments, the lower conductive pattern UCE, the upper conductive pattern FCE, and the contact electrode unit AE-CT of the first electrode may be arranged to be aligned in the thickness direction. For example, the lower conductive pattern UCE, the upper conductive pattern FCE, and the first electrode AE may be arranged in a vertical laminate structure while the stable contact is maintained according to the arrangement of the bridge pattern BRE and the flat insulation layer IVA positioned or arranged therebetween. Accordingly, as the connection electrode unit is introduced to dispose or arrange the conductive patterns so as to maintain the stable contact through vertical alignment, the display panel DP according to one or more embodiments may include the multiple conductive patterns arranged effectively or suitably within a limited area and exhibit the high resolution characteristics and the excellent or suitable electrical stability.

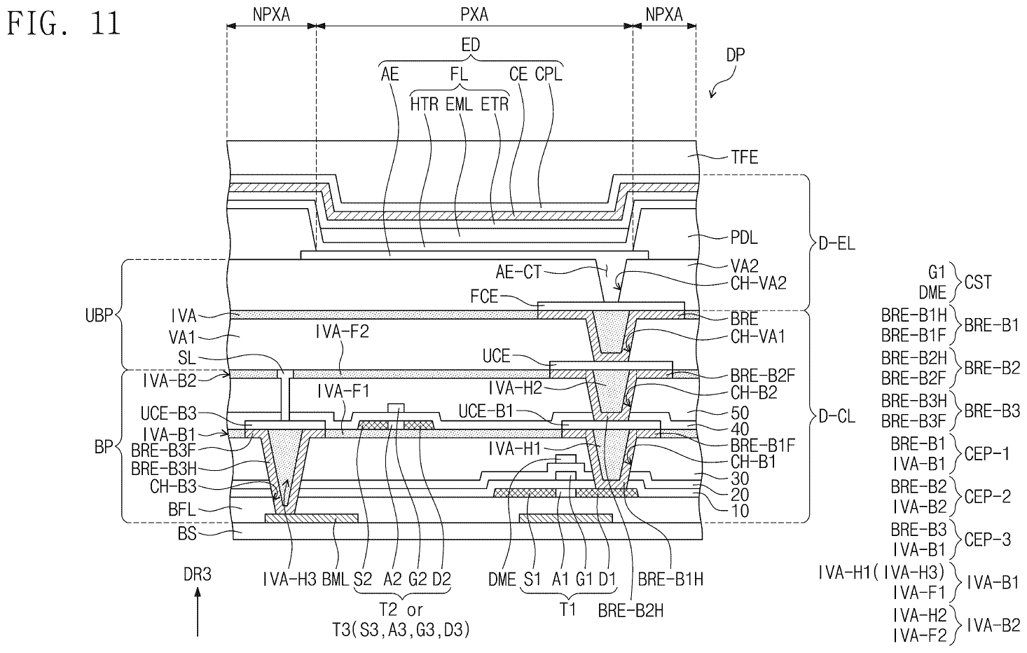

Hereinafter, a display panel according to one or more embodiments will be described in more detail with reference to FIGS. 11 to 14. In describing the display panel according to one or more embodiments with reference to FIGS. 11 to 14, the features as described with reference to FIGS. 1 to 10 may not be described again, and the different features may be mainly or predominantly described.

FIG. 11 is a cross-sectional view of a portion of the display panel according to one or more embodiments. In comparison to FIG. 9, FIG. 11 illustrates in more detail the configuration or arrangement of the lower circuit layer.

The lower circuit layer BP may include a plurality of conductive (e.g., electrically conductive) patterns and a plurality of interlayer insulation (e.g., electrical insulation) layers. One or more of the plurality of conductive patterns of the lower circuit layer BP may form a portion of transistors. The lower circuit layer BP may include, as conductive (e.g., electrically conductive) patterns, a shield pattern BML, transistors T1 and T2, a dummy electrode DME, signal lines SL, and/or the like. In one or more embodiments, bridge conductive units BRE-B1 and BRE-B2, flat conductive units UCE_B1 and UCE-B2, and/or the like may be further included as the conductive patterns.

The lower circuit layer BP may include, as interlayer insulation (e.g., electrical insulation) layers, a buffer layer BFL, first to fifth insulation layers 10, 20, 30, 40, and 50, and/or the like. In one or more embodiments, the lower circuit layer BP in one or more embodiments may further include interlayer insulation units IVA-B1 and IVA-B2 as the interlayer insulation layers.

The shield pattern BML may be arranged on a base layer BS. The shield pattern BML may be composed of a metal material. The shield pattern BML may be arranged to overlap a transistor T1 and/or the like to protect semiconductor patterns of the transistor T1. The shield pattern BML in one or more embodiments may be connected to electrodes or wirings SL to receive a prescribed constant voltage. Furthermore, the shield pattern BML in one or more embodiments may have a floating pattern isolated from other electrodes or wirings.

The buffer layer BFL may be arranged on the base layer BS. The buffer layer BFL may improve or enhance a bonding force between the base layer BS and semiconductor patterns S1, A1, and D1 and/or the shield pattern BML. The buffer layer BFL may cover the shield pattern BML. The buffer layer BFL may include at least one inorganic layer, for example, at least one of aluminum oxide, titanium oxide, silicon oxide, silicon nitride, silicon oxynitride, zirconium oxide, or hafnium oxide.

The first to fifth insulation layers 10, 20, 30, 40, and 50 may be arranged on the buffer layer BFL. The first to fifth insulation layers 10, 20, 30, 40, and 50 may be sequentially laminated in the third direction DR3. The lower insulation layer VA1 and the upper insulation layer VA2 may be sequentially arranged on the fifth insulation layer 50. FIG. 11 and/or the like illustrates that the interlayer insulation layer included in the lower circuit layer BP includes the first to fifth insulation layers 10, 20, 30, 40, and 50, but the number and laminate structure of the plurality of interlayer insulation layers included in the lower circuit layer D-CL are not limited thereto.

Referring to FIG. 11, the first transistor T1 may be arranged on the buffer layer BFL. The second transistor T2 may be arranged at an upper layer of the first opening unit T1.

The first semiconductor layer S1, A1, and D1 of the first transistor T1 may be arranged on the buffer layer BFL. The first semiconductor layer S1, A1, and D1 may include polysilicon. However, embodiments of the present disclosure are not limited thereto, and the first semiconductor layer S1, A1, and D1 may include amorphous (e.g., non-crystalline) silicon.

The first semiconductor layer S1, A1, and D1 may include a first source area S1, a first channel area A1, and a first drain area D1. The first channel area A1 may be arranged between the first source area S1 and the first drain area D1. The first source area S1 may correspond to the first electrode unit of the first transistor T1 as described in one or more embodiments. The first drain area D1 may correspond to the second electrode unit of the first transistor T1 as described in one or more embodiments.

The first source area S1 and the first drain area D1 may have the conductivity (e.g., electrical conductivity) through a doping process and substantially act or serve as a source electrode and a drain electrode of the first transistor T1. The first channel area A1 may substantially correspond to an active area of the first transistor T1.

The first insulation layer 10 may be arranged on the buffer layer BFL so as to cover the first semiconductor layer S1, A1, and D1. A first gate electrode G1 of the first transistor T1 may be arranged on the first insulation layer 10. If (e.g., when) viewed in plan view, the first gate electrode G1 may overlap the first channel area A1. The first gate electrode G1 may be a control electrode of the first transistor T1 to be connected to a first node N1. Substantially, the first gate electrode G1 may act or serve as the first node N1.

The second insulation layer 20 may be arranged on the first insulation layer 10 to cover the first gate electrode G1. The dummy electrode DME may be arranged on the second insulation layer 20. The dummy electrode DME may form the capacitor CST as described in one or more embodiments together with the first gate electrode G1. The first gate electrode G1 may define the first electrode unit of the capacitor CST, and the dummy electrode DME may define the second electrode unit of the capacitor CST.

The third insulation layer 30 may be arranged on the second insulation layer 20 so as to cover the dummy electrode DME. A second semiconductor layer S2, A2, and D2 of the second transistor T2 may be arranged on the third insulation layer 30. The second semiconductor layer S2, A2, and D2 may include a metal-oxide semiconductor of a metal oxide. The oxide semiconductor may include a crystalline oxide semiconductor and/or an amorphous (e.g., non-crystalline) oxide semiconductor.

The second semiconductor layer S2, A2, and D2 may include a second source area S2, a second channel area A2, and a second drain area D2. The second channel area A2 may be arranged between the second source area S2 and the second drain area D2. The second source area S2 may correspond to the second electrode unit of the second transistor T2 as described in one or more embodiments. The second drain area D2 may correspond to the first electrode unit of the second transistor T2 as described in one or more embodiments.

The second source area S2 and the second drain area D2 may have the conductivity (e.g., electrical conductivity) through a doping process and substantially act or serve as a source electrode and a drain electrode of the second transistor T2. The second channel area A2 may substantially correspond to an active area of the second transistor T2.

The fourth insulation layer 40 may be arranged on the third insulation layer 30 so as to cover the second semiconductor layer S2, A2, and D2. A second gate electrode G2 of the second transistor T2 may be arranged on the fourth insulation layer 40. The second gate electrode G2 may overlap the second channel area A2. The fifth insulation layer 50 may be arranged on the fourth insulation layer 40 so as to cover the second gate electrode G2.

In one or more embodiments, the structure of a third source area D3, a third channel area A3, a third drain area D3, and a third gate electrode G3 of a third transistor T3 arranged at substantially the same layer as the second transistor T2 may be substantially same as the structure of the second transistor T2.

The buffer layer BFL and the first to fifth insulation layers 10, 20, 30, 40, and 50 may include inorganic layers. By way of an example, the buffer layer BFL and the first insulation layer 10 may include silicon oxide layers, and the second insulation layer 20 may have a silicon nitride layer. The third insulation layer 30 may include different materials and a plurality of inorganic insulation (e.g., electrical insulation) layers laminated on each other. For example, the third insulation layer 30 may include a silicon nitride layer and a silicon oxide layer laminated on each other.

The fourth insulation layer 40 may include a silicon oxide layer. The fifth insulation layer 50 may include different materials and a plurality of inorganic insulation (e.g., electrical insulation) layers laminated on each other. For example, the fifth insulation layer 50 may include silicon oxide layers and silicon nitride layers laminated on each other.

The lower circuit layer BP in the display panel DP according to one or more embodiments may include at least one connection electrode unit CEP-1, CEP-2, or CEP-3. The connection electrode unit CEP-1, CEP-2, or CEP-3 may be a portion electrically connecting the conductive patterns spaced and/or apart (e.g., spaced apart or separated) from each other and positioned or arranged on the different layers in the thickness direction.

The connection electrode units CEP-1, CEP-2, and CEP-3 may respectively include the bridge conductive units BRE-B1, BRE-B2, and BRE-B3 and the interlayer insulation units IVA-B1 and IVA-B2. The interlayer insulation units IVA-B1 and IVA-B2 may include the first insulation units IVA-H1 and IVA-H2 and the second insulation units IVA-F1 and IVA-F2.

Referring to FIG. 11, the first connection electrode unit CEP-1 may electrically connect between the first semiconductor layer S1, A1, and D1, a contact hole CH-B2 defined in the fifth insulation layer 50, and the second bridge conductive unit BRE-B2 arranged to extend onto the fifth insulation layer 50. In one or more embodiments, the first semiconductor layer S1, A1, and D1 may correspond to the first conductive pattern, and the second bridge conductive unit BRE-B2 may correspond to the second conductive pattern.

The second connection electrode unit CEP-2 may electrically connect between the first bridge conductive unit BRE-B1 arranged to extend onto the third insulation layer 30 and an insulation opening CH-B1 defined through the first to third insulation layers 10, 20, and 30, and the bridge pattern BRE included in the upper circuit layer UNP. In one or more embodiments, the first bridge conductive layer BRE-B1 may correspond to the first conductive pattern, and the bridge pattern BRE may correspond to the second conductive pattern.

In one or more embodiments, the third connection electrode CEP-3 may electrically connect the shield pattern BML corresponding to the first conductive pattern and a signal line SL corresponding to the second conductive pattern and arranged on the fifth insulation layer 50.

The first connection electrode unit CEP-1 may include the first bridge conductive unit BRE-B1 and the first interlayer insulation unit IVA-B1. The first bridge conductive unit BRE-B1 may include a first bridge bending unit BRE-B1H and a first bridge flat unit BRE-B1F. The first bridge bending unit BRE-B1H may be arranged in the insulation opening CH-B1 defined through the first to third insulation layers 10, 20, and 30. The first bridge flat unit BRE-B1F may extend from the first bridge bending unit BRE-B1H to be arranged on the third insulation layer 30 that is the uppermost layer among the insulation layers in which the insulation opening CH-B1 is defined.

The first interlayer insulation unit IVA-B1 may include a first insulation unit IVA-H1 filling the insulation opening CH-B1 on the first bridge bending unit BRE-B1H and a second insulation unit IVA-F1 covering the side surfaces of the first bridge flat unit BRE-B1F and arranged on the third insulation layer 30. The top surface of the second insulation unit IVA-F1 may provide substantially the same plane as the top surface of the first bridge flat unit BRE-B1F. The top surface of the first insulation unit IVA-H1, the top surface of the second insulation unit IVA-F1, and the top surface of the first bridge flat unit BRE-B1F may be coplanar and define a flat surface (e.g., a substantially flat surface).

The second connection electrode unit CEP-2 may include a second bridge conductive unit BRE-B2 and a first interlayer insulation unit IVA-B2. The second bridge conductive unit BRE-B2 may include a second bridge bending unit BRE-B2H and a second bridge flat unit BRE-B2F. The second bridge bending unit BRE-B2H may be arranged in an insulation (e.g., electrical insulation) opening defined in the fifth insulation layer 50. The second bridge flat unit BRE-B2F may extend from the second bridge being unit BRE-B2H to be arranged on the fifth insulation layer 50.

The second interlayer insulation unit IVA-B2 may include a first insulation unit IVA-H2 filling the insulation opening CH-B2 on the second bridge bending unit BRE-B2H, and a second insulation unit IVA-F2 covering the side surfaces of the first bridge flat unit BRE-B2F and arranged on the fifth insulation layer 50. The top surface of the second insulation unit IVA-F2 may provide substantially the same plane as the top surface of the second bridge flat unit BRE-B2F. The top surface of the first insulation unit IVA-H2, the top surface of the second insulation unit IVA-F2, and the top surface of the second bridge flat unit BRE-B2F may be coplanar and define a flat surface (e.g., a substantially flat surface).

The third connection electrode CEP-3 may include the third bridge conductive unit BRE-B3 and the first interlayer insulation unit IVA-B1. The third bridge conductive unit BRE-B3 may include a third bridge bending unit BRE-B3H and a third bridge flat unit BRE-B3F. The third bridge bending unit BRE-B3H may be arranged in an insulation opening CH-B3 defined through the first to third insulation layers 10, 20, and 30. The third bridge flat unit BRE-B3F may extend from the third bridge unit BRE-B3H to be arranged on the third insulation layer 30 that is the uppermost layer among insulation (e.g., electrical insulation) layers in which the insulation opening CH-B3 is defined.

The first interlayer insulation unit IVA-B1 composing the third connection electrode unit CEP-3 may include a first insulation unit IVA-H3 filling the insulation opening CH-B3 on the third bridge bending unit BRE-B3H, and a second insulation unit IVA-F1 covering the side surfaces of the third bridge flat unit BRE-B3F and arranged on the third insulation layer 30. The top surface of the second insulation unit IVA-F1 may provide substantially the same plane as the top surface of the third bridge flat unit BRE-B3F. The top surface of the first insulation unit IVA-H3, the top surface of the second insulation unit IVA-F1, and the top surface of the third bridge flat unit BRE-B3F may be coplanar and define a flat surface (e.g., a substantially flat surface).

In one or more embodiments, the lower circuit layer BP may include the first connection electrode unit CEP-1 and the second connection electrode unit CEP-2 arranged on the first connection electrode unit CEP-1. The second connection electrode unit CEP-2 may electrically connect the bridge pattern BRE included in the upper circuit layer UBP and the first connection electrode unit CEP-1. The transistor T1 and the light-emitting element ED may electrically stably contact to be connected by the first connection electrode unit CEP-1, the second connection electrode unit CEP-2, and the bridge pattern BRE that are vertically aligned and the connection electrode unit of the upper portion including the flat insulation layer IVA. In one or more embodiments, due to the first connection electrode unit CEP-1, the second connection electrode unit CEP-2, and the bridge pattern BRE that are vertically aligned and the connection electrode unit of the upper portion including the flat insulation layer IVA, the conductive patterns connecting the first electrode AE of the light-emitting element ED and the transistor T1 may be integrated and arranged, thereby relatively easily achieving the high resolution of the display panel DP of one or more embodiments.

In one or more embodiments, FIG. 11 illustrates a case in which the lower circuit layer BP includes the three connection units CEP-1, CEP-2, and CEP3 in the one emission area PXA and the peripheral area NPXA adjacent to the emission area PXA of the display panel DP, but embodiments of the present disclosure are not limited thereto. In the one emission area PXA and the peripheral area NPXA adjacent to the emission area PXA, the lower circuit layer BP may not include (e.g., may exclude) the connection electrode unit (e.g., may exclude any connection electrode unit) or only include at most two connection electrode units. In one or more embodiments, in the one emission area PXA and the peripheral area NPXA adjacent to the emission area PXA, the lower circuit layer BP may include at least four connection electrode units.

The disposition shape and electrical connection relationship of the connection electrode units CEP-1, CEP-2, and CEP-3 as illustrated in FIG. 11 are an example. The connection electrode units are not limited to the layers as described in one or more embodiments and also be provided on another layer except the circuit layer D-CL as long as the connection units connect between the conductive patterns spaced and/or apart (e.g., spaced apart or separated) from each other in the thickness direction and include the bridge conductive unit and the interlayer insulation unit.

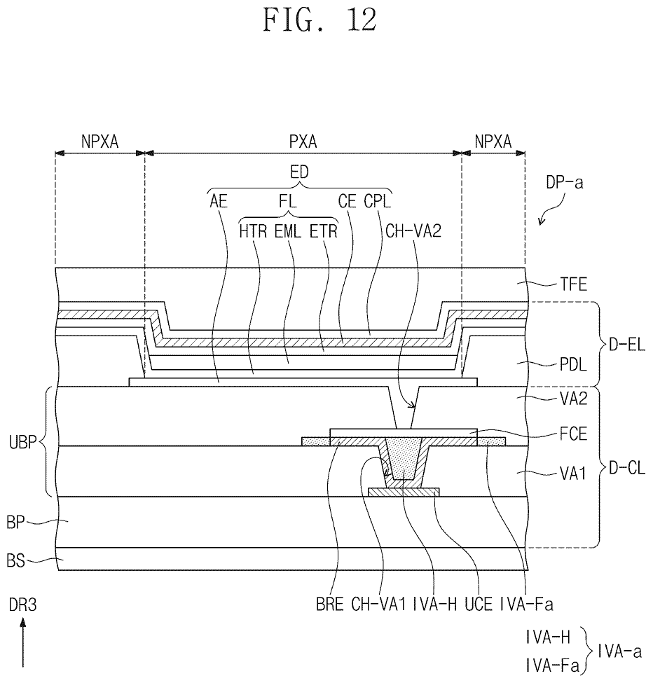

FIG. 12 is a cross-sectional view of a display panel DP-a according to one or more embodiments. The display panel DP-a according to one or more embodiments as illustrated in FIG. 12 may have the difference in disposition type (kind) or arrangement type (kind) of a flat insulation layer IVA-a in comparison to the display panel DP according to one or more embodiments as described with reference to FIGS. 9 and 10.

In one or more embodiments, the flat insulation layer IVA-a may include a fill insulation part IVA-H arranged on the bridge pattern BRE in the contact opening CH-VA1 and a flat insulation part IVA-Fa spaced and/or apart (e.g., spaced apart or separated) from the filling IVA-H insulation unit and arranged on the lower insulation layer VA1. In comparison to one or more embodiments, as illustrated in FIG. 9, the flat insulation part IVA-Fa of the FIG. 11 does not cover the entire top surface of the lower insulation layer VA1.

In one or more embodiments, the flat insulation part IVA-Fa may be arranged to cover an edge of the bridge pattern BRE arranged on the lower insulation layer VA1 and partially extend from the edge of the bridge pattern BRE. The flat insulation part IVA-Fa may be arranged on the lower insulation layer VA1 within a range in which the flat insulation part IVA-FA does not have a step on the lower insulation layer VA1 if (e.g., when) the upper conductive pattern FCE is arranged. In one or more embodiments, as illustrated in FIG. 12, an edge of the upper conductive pattern FCE may be arranged between the edge of the bridge pattern BRE and an edge of the flat insulation part IVA-Fa.

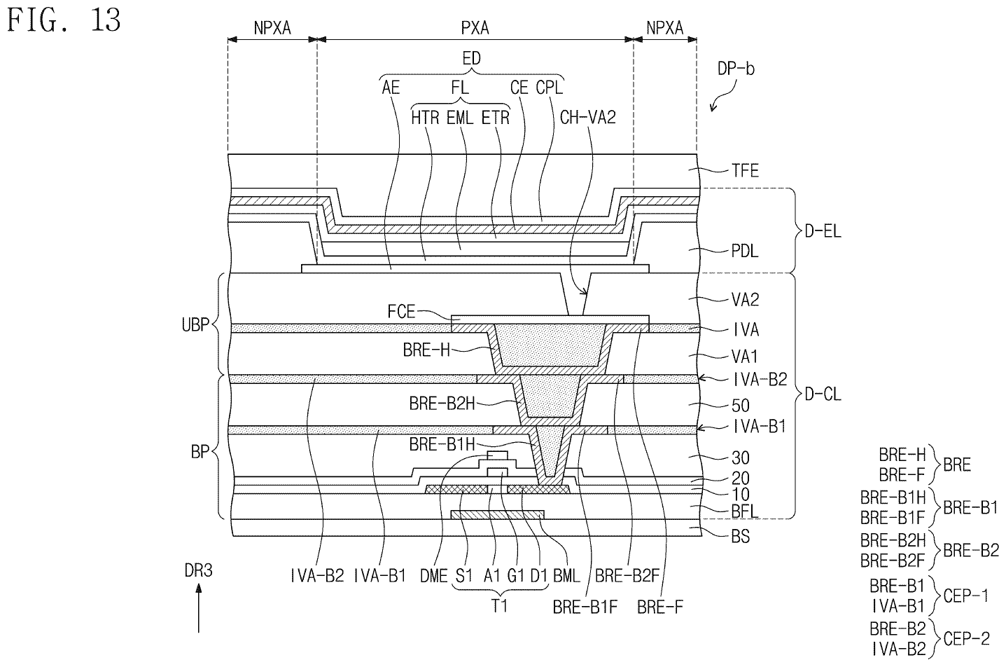

FIG. 13 is a cross-sectional view of a display panel DP-b according to one or more embodiments. In the display panel DP-b of one or more embodiments, the bridge conductive units BRE-B1 and BRE-B2 of the connection electrode units CEP-1 and CEP-2 may be arranged to be connected to each other.

The lower circuit layer BP may include the first connection electrode unit CEP-1 and the second connection electrode unit CEP-2 arranged on the first connection electrode unit CEP-1. At least a portion of the first connection electrode unit CEP-1 may be connected to the second connection electrode unit CEP-2. The first connection electrode unit CEP-1 and the second connection electrode unit CEP-2 may be utilized to electrically connect a first conductive (e.g., electrically conductive) pattern arranged under the first connection electrode unit CEP-1 and a second connection pattern arranged over the second connection electrode unit CEP-2. For example, in one or more embodiments, as illustrated in FIG. 13, the first conductive pattern may correspond to the first semiconductor layer A1, S1 and D1, and the second conductive pattern may correspond to the bridge pattern BRE.

The first connection electrode unit CEP-1 may include the first bridge conductive unit BRE-B1 and the first interlayer insulation unit IVA-B1. The first bridge conductive unit BRE-B1 may include the first bridge bending unit BRE-B1H and the first bridge flat unit BRE-B1F. The first bridge bending unit BRE-B1H may be arranged in the insulation opening defined through the interlayer insulation layers 10, 20, and 30, and the first bridge flat unit BRE-B1F may be arranged on the uppermost insulation layer 30 among the plurality of interlayer insulation layers defining the insulation opening.

The first interlayer insulation unit IVA-B1 may be arranged on the first bridge conductive unit BRE-B1 and fill the insulation opening. The top surface of the first bridge flat unit BRE-B1F composing the first connection electrode unit CEP-1 and the top surface of the first interlayer insulation unit IVA-B1 may be coplanar and define a flat surface (e.g., a substantially flat surface).

The second connection electrode unit CEP-2 may include the second bridge conductive unit BRE-B2 and the second interlayer insulation unit IVA-B2. The second bridge conductive unit BRE-B2 may include the second bridge bending unit BRE-B2H and the second bridge flat unit BRE-B2F. The second bridge bending unit BRE-B2H may be arranged in the insulation opening defined through the interlayer insulation layer 50, and the second bridge flat unit BRE-B2F may be arranged on the insulation layer 50 defining the insulation opening.

The second interlayer insulation unit IVA-B2 may be arranged on the second bridge conductive unit BRE-B2 and fill the insulation opening. The top surface of the second bridge flat unit BRE-B2F composing the second connection electrode unit CEP-2 and the top surface of the second interlayer insulation unit IVA-B2 may be coplanar and define a flat surface (e.g., a substantially flat surface).

In one or more embodiments, as illustrated in FIG. 13, the first bridge conductive unit BRE-B1 and the second bridge conductive unit BRE-B2 may be directly connected. In one or more embodiments, the first bridge flat unit BRE-B1F of the first bridge conductive unit BRE-B1 and the second bridge bending unit BRE-B2H of the second bridge conductive unit BRE-B2 may be directly connected. In one or more embodiments, the second bridge bending unit BRE-B2H may be arranged on the flat surface defined by the first bridge flat unit BRE-B1F and the first interlayer insulation unit IVA-B1, and accordingly, the first bridge conductive unit BRE-B1 and the second bridge conductive unit BRE-B2 may have the stable contact characteristics.

In one or more embodiments, as illustrated in FIG. 13, the bridge bending unit BRE-H of the bridge pattern BRE included in the upper circuit layer UBP may be directly connected to the second bridge flat unit BRE-B2F of the second bridge conductive unit BRE-B2 of the lower circuit layer BP.

In one or more embodiments, for stable contact, the width of the bridge bending units BRE-H and BRE-B2H arranged in an upper portion in one direction may be larger than the width of the bridge bending units BRE-B2H and BRE-B1H arranged in a lower portion in one direction. In one or more embodiments, the bridge bending units BRE-H and BRE-B2H arranged in the upper portion may be arranged to be connected to the bridge flat units BRE-B2F and BRE-B1F of the bridge conductive unit in the lower portion.

In one or more embodiments, upon the direct connection of the bridge conductive units BRE-B1 and BRE-B2 arranged to overlap in the thickness direction or the direction connection of the bridge conductive unit BRE-B2 and the bridge pattern BRE, the flatness of a connection part may be ensured to make a stable contact due to the interlayer insulation units IVA-B1 and IVA-B2 arranged in the lower portion.

FIG. 14 is a cross-sectional view of a display panel according to one or more embodiments. FIG. 14 illustrates a portion of the display panel DP-1 including the first to third emission areas PXA-B, PXA-G, and PXA-R and the peripheral area NPXA arranged therebetween. The display panel DP-1 according to one or more embodiments may include the base layer BS, the circuit layer D-CL including the lower circuit layer BP and the upper circuit layer UBP, the display layer D-EL, and the encapsulation layer TFE.

In one or more embodiments, the display layer D-EL may be sorted as a pixel definition layer PDL and include a first light-emitting element ED1, a second light-emitting element ED2, and a third light-emitting element ED3 that are to emit light at different wavelength regions. The first to third light emitting elements ED1, ED2, and ED3 may respectively include the first electrodes AE, functional layers FL1, FL2, and FL3, and the second electrodes CE. In FIG. 14, first to third functional layers F1, F2, and F3 are illustrated to be arranged as common layers in all the first to third emission areas PXA-B, PXA-G, and PXA-R, but a portion of the layers composing the first to third functional layers F1, F2, and F3 may be respectively arranged in the first to third emission areas PXA-B, PXA-G, and PXA-R.

For example, the first to third functional layers F1, F2, and F3 each include an emission layer, and a first emission layer included in the first functional layer FL1, a second emission layer included in the second functional layer FL2, and a third emission layer included in the third functional layer FL3 may be respectively arranged corresponding to pixel openings defined in the pixel definition layer PDL. Accordingly, the first light-emitting element ED1, the second light-emitting element ED2, and the third light-emitting element ED3 may be to emit light beams at different wavelength regions.

In one or more embodiments, the first light-emitting element ED1, the second light-emitting element ED2, and the third light-emitting element ED3 each may be electrically connected to a plurality of transistors, signal lines, control lines, and/or the like arranged in the lower circuit layer BP via the connection electrode unit of the circuit layer D-CL.

The connection electrode unit may include the bridge pattern BRE and the flat insulation layer IVA. The flat insulation layer IVA may include the fill insulation part IVA-H arranged on the bending portion of the bridge pattern BRE to flatten the bending portion and the flat insulation part IVA-F spaced and/or apart (e.g., spaced apart or separated) from the fill insulation part IVA-H to cover the side surfaces of the bridge pattern BRE. In one or more embodiments, the connection electrode unit may include upper conductive patterns FCE1, FCE2, and FCE3. The upper conductive patterns FCE1, FCE2, and FCE3 may correspond to flat (e.g., substantially flat) conductive (e.g., electrically conductive) patterns that are flatly arranged on the fill insulation part IVA-H and the bridge pattern BRE. Due to the upper conductive patterns FCE1, FCE2, and FCE3 that are the flat conductive patterns, the first electrodes AE of the first to third light-emitting elements ED1, ED2, and ED3 may maintain the configuration or arrangement and stable contact of the lower circuit layer BP.

In the display panel DP-1 according one or more embodiments, the distances between the functional layers FL1, FL2, and FL3 of the first to third light-emitting elements ED1, ED2, and ED3 configured or arranged to emit light beams of different wavelength regions and the upper conductive patterns FCE1, FCE2, and FCE3 may be different from each other. In consideration of the wavelengths of the light beams emitted from the light-emitting elements ED1, ED2, and ED3, the distances between the functional layers FL1, FL2, and FI3 including the emission layer and the upper conductive patterns FCE1, FCE2, and FCE3 may be adjusted. The resonance distances may be adjusted considering the wavelengths of the light beams emitted from the light-emitting elements ED1, ED2, and ED3, and the resonance distances in one or more embodiments may be adjusted by differentiating the distances between the functional layers FL1, FL2, and FL3 and the upper conductive patterns FCE1, FCE2, and FCE3.

In one or more embodiments, as illustrated in FIG. 14, the distance d1 between the first functional layer FL1 and the first upper conductive pattern FCE1, the distance d2 between the second functional layer FL2 and the second upper conductive pattern FCE2, and the distance d3 between the third functional layer FL3 and the third upper conductive pattern FCE3 may be different from each other. For example, the first light-emitting element ED1 may be to emit blue light, the second light-emitting element ED2 may be to emit green light, and the third light-emitting element ED3 may be to emit red light, and, in one or more embodiments, the distances d1, d2, and d3 between the functional layers FL1, FL2, and FL3 and the upper conductive patterns FCE1, FCE2, and FCE3 may be adjusted to have the relation of d1<d2<d3.

In one or more embodiments, the upper conductive patterns FCE1, FCE2, and FCE3 may be provided to overlap all the emission areas PXA-B, PXA-G, and PXA-R defined by the pixel definition layer PDL. On the cross section parallel (e.g., substantially parallel) to the third directional axis DR3, the width WFCE of the upper conductive patterns FCE1, FCE2, and FCE3 in one direction may be at least the width WOP of an opening region defined in the pixel definition layer PDL. Accordingly, a substantially uniform resonance effect may be exhibited in the emission areas PXA-B, PXA-G, and PXA-R. In one or more embodiments, the upper conductive patterns FCE1, FCE2, and FCE3 may be provided from a material having the excellent or suitable reflection characteristics, and the first electrode AE may be provided from a material having the high transmittance characteristics, and thus the functional layers FL1, FL2, and FL3 may optimally resonate with the upper conductive patterns FCE1, FCE2, and FCE3. Thus, the display panel DP-1 according to one or more embodiments may exhibit the excellent or suitable display quality.

In one or more embodiments, even if (e.g., when) the distances between the functional layers FL1, FL2, and FL3 including the emission layer and the upper conductive patterns FCE1, FCE2, and FCE3 are differently adjusted considering the resonance distance for each wavelength, the first electrodes AE of the light-emitting elements ED1, ED2, and ED3 may stably contact the connection electrode unit including gaps between the upper conductive patterns FCE1, FCE2, and FCE3. Thus, the display panel DP-1 according to one or more embodiments may exhibit the excellent or suitable electrical reliability and display quality.

The display panel according to one or more embodiments and the display device according to one or more embodiments as described with reference to FIGS. 4 to 14 may be to generate and provide an image. The electronic device EA (FIG. 1) according to one or more embodiments may include the display panel according to one or more embodiments and include the display module DM (FIG. 1) configured or arranged to provide an image. The electronic device EA (FIG. 1) according to one or more embodiments may include the display module DM (FIG. 1) including the display panel according to one or more embodiments and the power module PM (FIG. 1) configured or arranged to supply power to the display module. The electronic device EA (FIG. 1) according to one or more embodiments may include the display module DM (FIG. 1) including the display panel according to one or more embodiments and exhibit the excellent or suitable electrical stability, the improved or enhanced reliability, and the excellent or suitable display quality characteristics.

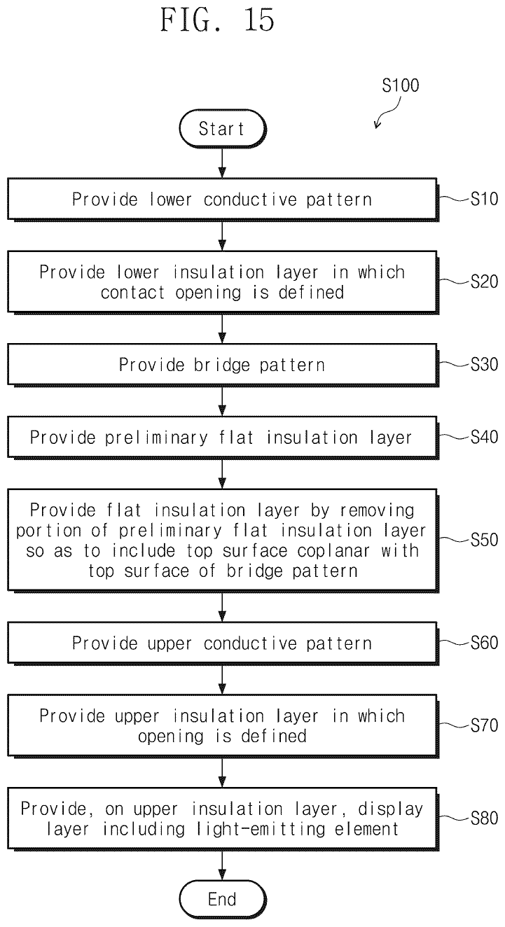

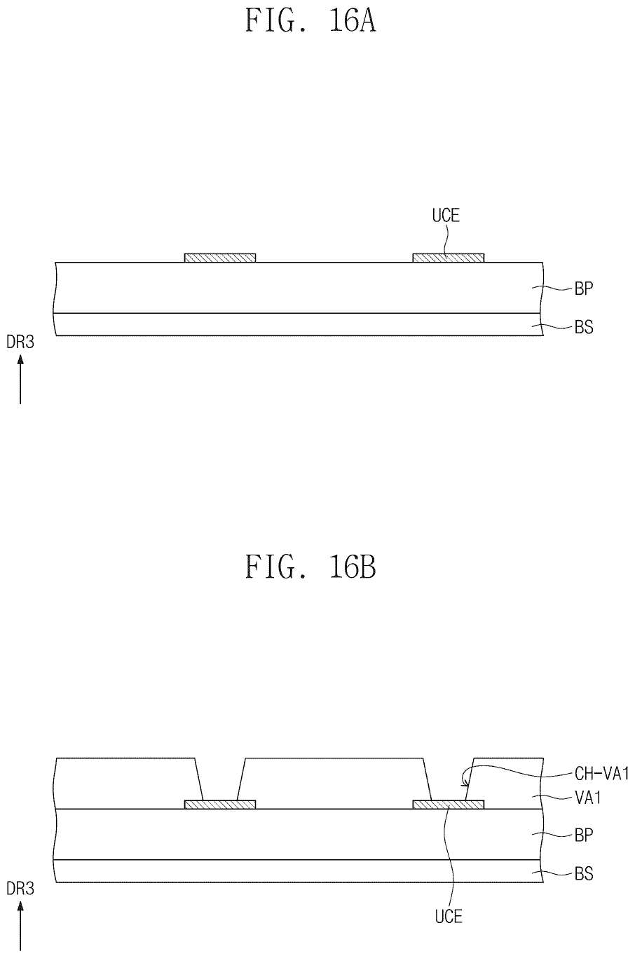

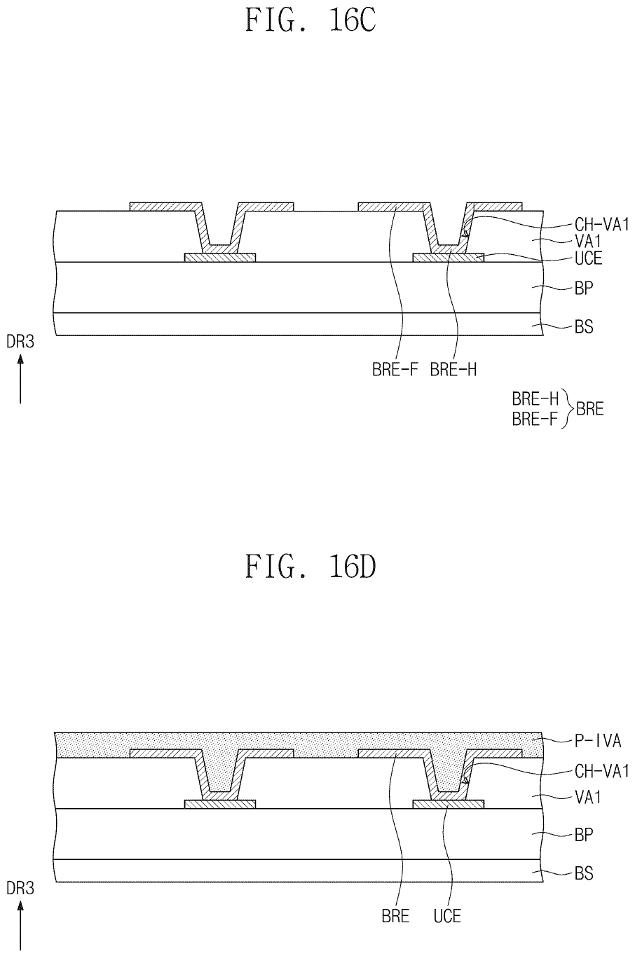

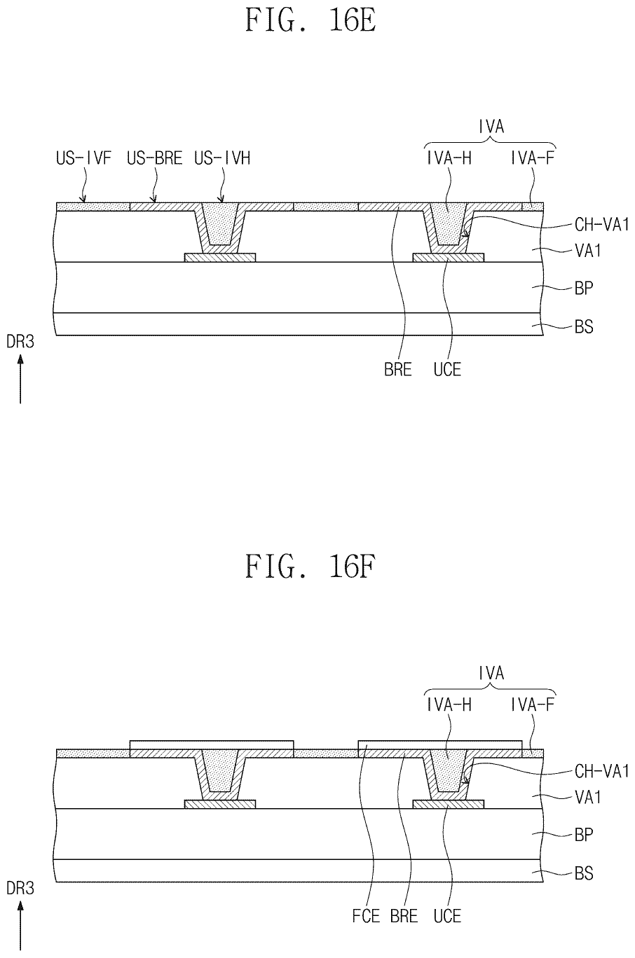

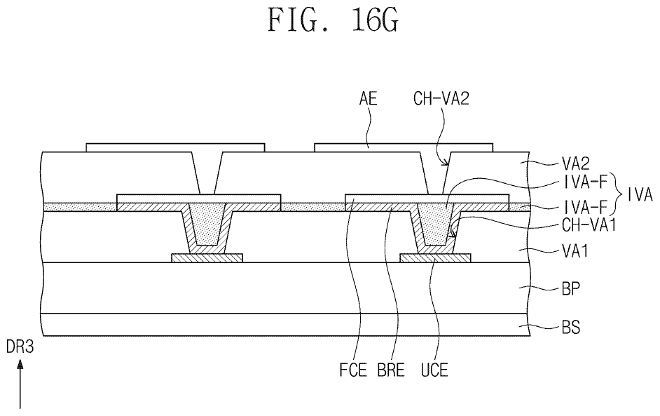

Hereinafter a display panel manufacturing method (e.g., a method of manufacturing a display panel) according to one or more embodiments will be described with reference to FIGS. 15 to 16G. In describing the display panel manufacturing method according to one or more embodiments, overlapping features with those as described with reference to FIGS. 1 to 14 may not be described again, and different features may be mainly or predominantly described.

FIG. 15 is a flowchart of a display panel manufacturing method according to one or more embodiments. FIGS. 16A to 16G each illustrates one example step (e.g., act or task) of the display panel manufacturing method according to one or more embodiments.

The display panel manufacturing method S100 according to one or more embodiments may include a step (e.g., act or task) to provide a lower conductive (e.g., electrically conductive) pattern (step (e.g., act or task) S10), a step (e.g., act or task) to provide a lower insulation (e.g., electrical insulation) layer in which a contact opening is defined (step (e.g., act or task) S20), a step (e.g., act or task) to provide a bridge pattern (step (e.g., act or task) S30), a step (e.g., act or task) to provide a preliminary flat (e.g., substantially flat) insulation (e.g., electrical insulation) layer (step (e.g., act or task) S40), a step (e.g., act or task) to remove a portion of the preliminary flat insulation layer to provide a flat (e.g., substantially flat) insulation (e.g., electrical insulation) layer (step (e.g., act or task) S50), a step (e.g., act or task) to provide an upper conductive (e.g., electrically conductive) pattern (step (e.g., act or task) S60), a step (e.g., act or task) to provide an upper insulation (e.g., electrical insulation) layer in which an opening is defined (step (e.g., act or task) S70), and a step (e.g., act or task) to provide a display layer on the upper insulation layer (step (e.g., act or task) S80).

FIG. 16A illustrates an example step (e.g., act or task) to provide a lower conductive (e.g., electrically conductive) pattern (step (e.g., act or task) S10). The lower conductive pattern UCE may be provided over the lower circuit layer BP arranged on the base layer BS. The lower conductive pattern UCE may be patterned to be provided on the lower circuit layer BP.

In one or more embodiments, but the lower circuit layer BP may include a plurality of conductive (e.g., electrically conductive) patterns and a plurality of interlayer insulation (e.g., electrical insulation) layers. The lower conductive pattern UCE may be electrically connected to at least one of the conductive patterns of the lower circuit layer BP.

FIG. 16B illustrates an example step (e.g., act or task) to provide a lower insulation (e.g., electrical insulation) layer (step (e.g., act or task) S20). The lower insulation layer VA1 may be arranged on the lower circuit layer BP. The contact opening CH-VA1 may be defined in the lower insulation layer VA1. At least a portion of the top surface of the lower conductive pattern UCE may be exposed in the contact opening CH-VA1.

FIG. 16C illustrates an example step (e.g., act or task) to provide a bridge pattern (step (e.g., act or task) S30). The bridge pattern BRE may be provided to be arranged along a bend of the contact opening CH-VA1 and partially extend to the top surface of the lower insulation layer VA1. The bridge pattern BRE may be patterned and provided to include the bending unit BRE-H arranged in the contact opening CH-VA1 and the flat unit BRE-F extending from the bending unit BRE-H to be arranged on the lower insulation layer VA1.

FIG. 16D illustrates an example step (e.g., act or task) to provide a preliminary flat insulation (e.g., electrical insulation) layer (step (e.g., act or task) S40). The preliminary flat insulation layer P-IVA may cover the bridge pattern BRE to be provided on the lower insulation layer VA1. The preliminary flat insulation layer P-IVA may be provided to have a sufficient or suitable thickness to fill the step (e.g., act or task) of the contact opening CH-VA1.

FIG. 16E illustrates an example step (e.g., act or task) to remove a portion of the preliminary flat insulation layer to provide a flat (e.g., substantially flat) insulation (e.g., electrical insulation) layer (step (e.g., act or task) S50). The preliminary flat insulation layer provided in the step (e.g., act or task) to provide a preliminary flat insulation (e.g., electrical insulation) layer (step (e.g., act or task) S40) may be removed to provide the flat insulation layer IVA so as to include a top surface being coplanar with the top surface of the bridge pattern BRE.

The flat insulation layer IVA may include the fill insulation part IVA-H and the flat insulation part IVA-F. The flat insulation layer IVA may be provided so that (or such that) the fill insulation part top surface US-IVH of the flat insulation layer IVA, the top surface of the flat insulation part IVA-F of the flat insulation layer IVA, and the bridge pattern top surface US-BRE are coplanar.

The step (e.g., act or task) to provide the flat insulation layer (step (e.g., act or task) S50) may include a step (e.g., act or task) to flatten the top surface of the preliminary flat insulation layer by at least one method among chemical mechanical polishing or etching. Upon removal of the preliminary flat insulation layer P-IVA, the flattening step (e.g., act or task) may be performed in consideration of an etching selectivity between the preliminary flat insulation layer P-IVA and the bridge pattern BRE, and accordingly the flat insulation layer IVA may be flattened to have the top surface coplanar with the top surface of the bridge pattern BRE.

In the context of one or more embodiments and unless defined otherwise, chemical mechanical polishing (CMP) and etching are both techniques used to smooth and shape surfaces, but they operate differently.

CMP combines chemical and mechanical forces to smooth surfaces. It utilizes an abrasive and corrosive chemical slurry along with a polishing pad. The wafer and pad are pressed together and rotated, which removes material and evens out irregularities, making the surface flat or planar.

Etching involves removing material from a surface using chemical reactions. There are different types of etching, such as wet etching (using liquid chemicals) and dry etching (using gases). Etching selectively removes material based on its position, creating patterns or designs on the surface.

As the flat insulation layer IVA is provided so that (or such that) the fill insulation part top surface US-IVH, the top surface of the flat insulation part IVA-F, and the bridge pattern top surface US-BRE are coplanar, the conductive pattern arranged on the flat insulation layer IVA may be provided to have a flat surface (e.g., a substantially flat surface) without a step.

FIG. 16F illustrates an example step (e.g., act or task) to provide an upper conductive (e.g., electrically conductive) pattern (step (e.g., act or task) S60). The upper conductive pattern FCE may be provided on the bridge pattern BRE. The upper conductive pattern FCE may be arranged on the flat surface provided by the bridge pattern BRE and the flat insulation layer IVA. Accordingly, the upper conductive pattern FCE may be provided to the flat surface without a step and/or a bend.

The upper conductive pattern FCE may be provided in a large area so as to overlap all the bridge pattern BRE and the fill insulation part IVA-H arranged on the lower insulation layer VA1. As the upper conductive pattern FCE has the flat (e.g., substantially flat) top surface and is provided in a large area, the arrangement position of a portion connected to the conductive pattern to which an upper portion of the upper conductive pattern FCE is connected may become wide to a range of the area of the upper conductive pattern, thereby increasing or enhancing the degree of freedom of the arrangement position of a conductive (e.g., electrically conductive) unit or a connection unit for electrical connection with the upper conductive pattern. In case of the display panel manufacturing method according to one or more embodiments, the arrangement positions of the conductive patterns (or electrode) for electrical connection between the conductive patterns of the circuit layer and the light-emitting elements of the display layer may be allowed to be vertically aligned. Accordingly, manufacturing a display panel with a high resolution may be enabled or feasible.

FIG. 16G illustrates an example portion of the step to provide a display layer on the upper insulation layer (step (e.g., act or task) S80). FIG. 16G illustrates a step to provide the first electrode AE of the light-emitting element included in the display layer. The first electrode AE may be provided on the upper insulation layer VA2.

The step (e.g., act or task) to provide the display layer on the upper insulation layer (step (e.g., act or task) S80) may be performed after the step (e.g., act or task) to provide the upper insulation layer. The upper insulation layer VA2 may be provided on the upper conductive pattern FCE. The opening CH-VA2 exposing a portion of the top surface of the upper conductive pattern FCE may be defined in the upper insulation layer VA2. The first electrode AE may be provided to fill the opening CH-VA2 of the upper insulation layer VA2 and extend onto the upper insulation layer VA2.

After the first electrode AE is provided, the pixel definition layer of the display layer may be provided so that (or such that) a pixel opening is defined, and then the functional layer, the second electrode, and/or the like may be sequentially provided to compose the display layer.

The display panel manufacturing method according to one or more embodiments may include the step (e.g., act or task) to provide the bridge pattern, and then the step (e.g., act or task) to provide the preliminary flat insulation layer, and the step (e.g., act or task) to remove the preliminary flat insulation layer to provide the flat insulation layer. In the method, the flat surface may be provided so that (or such that) the top surface of the flat insulation layer is coplanar with the top surface of the bridge pattern, and the connection electrode unit including the bridge pattern and the flat insulation layer may be introduced to be utilized for manufacturing a display panel with the improved or enhanced electrical contact stability.

In one or more embodiments, the display panel manufacturing method according to one or more embodiments may be utilized to manufacture a display panel with improved or enhanced display quality by providing the flat insulation layer including the fill insulation part arranged in the contact opening and a flat (e.g., substantially flat) insulation (e.g., electrical insulation) part spaced and/or apart (e.g., spaced apart or separated) from the fill insulation part and not overlapping the bridge pattern, and allowing the conductive pattern to be arranged on the upper portion of the flat insulation layer without a step and/or a bend to reduce light scattering that may occur due to the bend of the upper conductive pattern.

The display panel according to one or more embodiments and the electronic device including the display panel may include the connection electrode unit having the flat (e.g., substantially flat) top surface in the circuit layer to stabilize an electrical connection between the conductive patterns spaced and/or apart (e.g., spaced apart or separated) from each other in the thickness direction, thereby exhibiting the excellent or suitable electrical reliability. In one or more embodiments, the connection electrode unit included in the display panel according to one or more embodiments may include the fill insulation part filling a bending unit of the bridge pattern having the bending unit, include the flat insulation part arranged outside the edge of the bridge pattern, and be provided so that (or such that) the conductive pattern arranged over the bridge pattern has the flat surface without a step. Accordingly, the display panel according to one or more embodiments and the electronic device including the display panel may reduce light scattering (or a degree or occurrence of light scattering) of reflected light caused by the step of the conductive pattern, thereby exhibiting the excellent or suitable display quality.

The connection electrode unit included in the display panel according to one or more embodiments may have the conductive pattern arranged in a sufficient or suitable area on the top surface flattened with the flat insulation layer and the bridge pattern. Accordingly, in one or more embodiments, the arrangement position of a connection portion electrically connected with the conductive pattern arranged on the upper portion of the upper conductive pattern may be secured widely across the area of the upper conductive pattern, thereby providing a wide choice in selecting the arrangement position of the conductive pattern in the circuit layer and the arrangement position of the electrode in the display layer. Accordingly, the plurality of conductive patterns may be arranged to stably contact each other within a limited planar area in the thickness direction to enable implementation of the display panel of a high resolution.

The display panel according to one or more embodiments and the electronic device including the display panel may include the connection electrode unit connecting the two conductive patterns spaced and/or apart (e.g., spaced apart or separated) in the thickness direction in the circuit layer, wherein the connection electrode unit includes the flat insulation layer having the fill insulation part filling the bending unit of the bridge pattern and the flat insulation part arranged at an edge unit of the bridge pattern, thereby improving or enhancing the contact stability between the upper conductive pattern and the lower conductive pattern. In one or more embodiments, due to the excellent or suitable contact stability and the flat arrangement of the conductive patterns on the flat insulation part, the display panel and the electronic device including the display panel may exhibit the improvement or enhancement in light scattering caused by a step between the conductive patterns and the excellent or suitable display quality.

The display panel manufacturing method (or the method of manufacturing the display panel) according to one or more embodiments may include a step (e.g., act or task) to flatten the top surface of the preliminary flat insulation layer provided on the bridge pattern to provide the flat insulation layer, and thus may be utilized to manufacture the display panel with the improved or enhanced electrical reliability and display quality.

For example, one or more embodiments of the present disclosure describe a display panel and an electronic device that include a connection electrode unit with a flat top surface in the circuit layer to stabilize electrical connections between conductive patterns spaced and/or apart (e.g., spaced apart or separated) in the thickness direction, ensuring excellent or enhanced electrical reliability. The connection electrode unit features a fill insulation part in the bending unit of the bridge pattern and a flat insulation part outside the bridge pattern edge, providing a flat surface for the conductive pattern above the bridge pattern. This design reduces light scattering caused by steps in the conductive pattern, enhancing display quality. The connection electrode unit also allows for a wide choice in arranging connection portions, enabling high-resolution display panels. The manufacturing method includes flattening the top surface of a preliminary flat insulation layer on the bridge pattern to create a flat insulation layer, improving or enhancing electrical reliability and display quality.

The present disclosure has been described with reference to one or more embodiments as illustrated in the drawings, but this is merely examples, and those skilled in the art will understand that one or more suitable modifications and other equivalent embodiments are possible therefrom. Therefore, the scope of the present disclosure should be determined by the appended claims and equivalents thereof.

It should be understood that embodiments as described herein should be considered in a descriptive sense only and not for purposes of limitation. Descriptions of features or aspects within each embodiment should be considered as available for other similar features or aspects in one or more embodiments.

What is claimed is:

1. A display panel comprising:
a base layer;
a circuit layer on the base layer; and
a display layer on the circuit layer and comprising a light-emitting element comprising a first electrode, a second electrode being opposite to the first electrode, and a functional layer between the first electrode and the second electrode,
wherein the circuit layer comprises:
a lower circuit layer comprising a plurality of conductive patterns and a plurality of interlayer insulation layers;
a lower conductive pattern on the lower circuit layer;
a lower insulation layer on the lower conductive pattern and having a contact opening defined to expose a top surface of the lower conductive pattern;
a bridge pattern directly on the lower conductive pattern in the contact opening and arranged to extend to a top surface of the lower insulation layer;
a flat insulation layer comprising a fill insulation part filling the contact opening and a flat insulation part spaced from the fill insulation part and not overlapping the bridge pattern to be on the lower insulation layer;
an upper conductive pattern arranged flat on the fill insulation part and the bridge pattern and electrically connected to the first electrode; and
an upper insulation layer on the upper conductive pattern.

2. The display panel as claimed in claim 1, wherein a top surface of the bridge pattern, a top surface of the fill insulation part, and a top surface of the flat insulation part are coplanar.

3. The display panel as claimed in claim 1, wherein a bottom surface of the upper conductive pattern is arranged to be spaced from the lower insulation layer with the bridge pattern or the flat insulation layer therebetween.

4. The display panel as claimed in claim 1, wherein an edge of the upper conductive pattern overlaps the bridge pattern.

5. The display panel as claimed in claim 1, wherein an edge of the upper conductive pattern overlaps the flat insulation part.

6. The display panel as claimed in claim 1, wherein side edges of the bridge pattern on the lower insulation layer are covered with the flat insulation part.

7. The display panel as claimed in claim 1, wherein the fill insulation part is surrounded by the bridge pattern and the upper conductive pattern.

8. The display panel as claimed in claim 1, wherein the first electrode comprises:
a contact electrode unit in an opening defined in the upper insulation layer to directly contact the upper conductive pattern; and
a flat electrode unit provided integrally with the contact electrode unit to be on the upper insulation layer.

9. The display panel as claimed in claim 1,
wherein the lower circuit layer further comprises a first conductive pattern and a second conductive pattern that are spaced from each other in a thickness direction and at least one connection electrode unit between the first conductive pattern and the second conductive pattern, and
wherein the at least one connection electrode unit comprises:
a bridge conductive unit comprising a bridge bending unit in an insulation opening defined through at least one of the plurality of interlayer insulation layers, and a bridge flat unit extending from the bridge bending unit to be on an uppermost layer among the plurality of interlayer insulation layers in which the insulation opening is defined; and
an interlayer insulation unit comprising a first insulation unit filling the insulation opening on the bridge bending unit and a second insulation unit having a top surface coplanar with a top surface of the bridge conductive unit and arranged on the uppermost layer.

10. The display panel as claimed in claim 9, wherein the at least one connection electrode unit further comprises a flat conductive unit arranged flat on the first insulation unit and the bridge flat unit and is electrically connected with the bridge conductive unit.

11. The display panel as claimed in claim 9,
wherein the circuit layer further comprises:
a first connection electrode unit connected to the first conductive pattern and comprising a first bridge conductive unit and a first interlayer insulation unit; and
a second connection electrode unit on the first connection electrode unit and comprising a second bridge conductive unit and a second flat insulation part, and
wherein each of the first bridge conductive unit and the second bridge conductive unit comprises the bridge bending unit and the bridge flat unit, and the bridge flat unit of the first bridge conductive unit is directly connected with the bridge bending unit of the second bridge conductive unit.

12. The display panel as claimed in claim 1,
wherein the display layer further comprises a first light-emitting element comprising a first functional layer, a second light-emitting element comprising a second functional layer, and a third light-emitting element comprising a third functional layer, wherein the first light-emitting element, the second light-emitting element, and the third light-emitting element are to emit light beams in different wavelength regions, and
wherein the circuit layer further comprises a first upper conductive pattern electrically connected with the first light-emitting element, a second upper conductive pattern electrically connected with the second light-emitting element, and a third upper conductive pattern electrically connected with the third light-emitting element, wherein a distance between the first functional layer and the first upper conductive pattern, a distance between the second functional layer and the second upper conductive pattern, and a distance between the third functional layer and the third upper conductive pattern are different from each other.

13. An electronic device comprising:
a display module comprising a display panel and arranged to provide an image; and
a power module to supply power to the display module,
wherein the display panel comprises:
a base layer;
a circuit layer on the base layer; and
a display layer on the circuit layer and comprising a light-emitting element comprising a first electrode, a second electrode being opposite to the first electrode, and a functional layer between the first electrode and the second electrode,
wherein the circuit layer comprises:
a lower circuit layer comprising a plurality of conductive patterns and a plurality of interlayer insulation layers;
a lower conductive pattern on the lower circuit layer;
a lower insulation layer on the lower conductive pattern and having a contact opening defined to expose a top surface of the lower conductive pattern;
a bridge pattern directly on the lower conductive pattern in the contact opening and arranged to extend to a top surface of the lower insulation layer;
a flat insulation layer comprising a fill insulation part filling the contact opening and a flat insulation part spaced from the fill insulation part and not overlapping the bridge pattern to be on the lower insulation layer;
an upper conductive pattern arranged flat on the fill insulation part and the bridge pattern and electrically connected to the first electrode; and
an upper insulation layer on the upper conductive pattern.

14. The electronic device as claimed in claim 13,
wherein the display module further comprises a light control panel on the display panel, and
wherein the light control panel comprises a color filter layer and a lens pattern on the color filter layer.

15. The electronic device as claimed in claim 13, further comprising at least one of a processor or a memory,
wherein the electronic device is an image display device, a wearable device, or a vehicle device.

16. The electronic device as claimed in claim 13, wherein:
the bridge pattern comprises a bridge bending unit in the contact opening and a bridge flat unit extending from the bridge bending unit to be on the lower insulation layer; and
a top surface of the bridge flat unit, a top surface of the fill insulation part, and a top surface of the flat insulation part are coplanar.

17. The electronic device as claimed in claim 13, wherein:
side edges of the bridge pattern on the lower insulation layer are covered with the flat insulation part; and
the fill insulation part is surrounded by the bridge pattern and the upper conductive pattern.

18. A method comprising:
providing a lower conductive pattern over a lower circuit layer on a base layer;
providing a lower insulation layer in which a contact opening is defined to expose at least a portion of a top surface of the lower conductive pattern;
providing a bridge pattern, the bridge pattern comprising a bending unit in the contact opening and a flat unit extending from the bending unit to be on the lower insulation layer;
providing a preliminary flat insulation layer, the preliminary flat insulation layer covering the bridge pattern and is on the lower insulation layer;
providing a flat insulation layer by removing a portion of the preliminary flat insulation layer so as to comprise a top surface that is coplanar with a top surface of the bridge pattern;
providing an upper conductive pattern on the bridge pattern;
providing an upper insulation layer in which an opening is defined to expose at least a portion of a top surface of the upper conductive pattern; and
providing, on the upper insulation layer, a display layer, the display layer comprising a light-emitting element electrically connected with the upper conductive pattern,
wherein the method is a method of manufacturing a display panel.

19. The method as claimed in claim 18, wherein the providing of the flat insulation layer comprises flattening a top surface of the preliminary flat insulation layer with at least one of chemical mechanical polishing or etching.

20. The method as claimed in claim 19, wherein the providing of the flat insulation layer comprises providing the flat insulation layer on the bending unit such that the flat insulation layer comprises a fill insulation part on the bending unit in the contact opening and a flat insulation part spaced from the fill insulation part, not overlapping the bridge pattern.
